(19) United States
(12) Patent Application Publication
(10) Pub. No.: US 2026/0206411 A1
(43) Pub. Date: Jul. 16, 2026

(54) Efficient and Stable all Phosphorescent Organic Light Emitting Diodes with Excellent Color Stability

(71) Applicant: Arizona Board of Regents on behalf of Arizona State University, Scottsdale, AZ (US)

(72) Inventors: Jian Li, Tempe, AZ (US); Aden Seeglitz, Glendale, AZ (US)

(21) Appl. No.: 19/566,452

(22) Filed: Mar. 13, 2026

Related U.S. Application Data
(63) Continuation-in-part of application No. 19/295,804, filed on Aug. 11, 2025.
(60) Provisional application No. 63/683,954, filed on Aug. 16, 2024.
(60) Provisional application No. 63/772,966, filed on Mar. 17, 2025.

(51) Int. Cl. H10K 50/165; H10K 50/12; H10K 85/30; H10K 85/40; H10K 85/60; H10K 101/00; H10K 102/00

(52) U.S. Cl. CPC H10K 50/165; H10K 50/12; H10K 85/346; H10K 85/40; H10K 85/654; H10K 85/6572; H10K 2101/90; H10K 2102/351

(57) ABSTRACT

An organic light emitting device comprises a substrate, a first electrode over the substrate, an emissive layer over the first electrode comprising a first thin emissive sub-layer and a second thin emissive sub-layer over the first, and a second electrode over the emissive layer.

### CROSS-REFERENCE TO RELATED APPLICATIONS

This application claims priority to U.S. Provisional Application No. 63/772,966, filed Mar. 17, 2025, which is incorporated herein in its entirety. This application is also a continuation-in-part of, and claims priority to, U.S. patent application Ser. No. 19/295,804, filed Aug. 11, 2025, which claims priority to U.S. Provisional Application No. 63/683,954 filed on Aug. 16, 2024, each of which applications is incorporated herein by reference in its entirety.

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

In recent years, organic light emitting diodes (OLEDs) have attracted great attention from both academic and industrial areas due to their outstanding merits, like high color quality, wide-viewing angle, low-cost fabrication, low power consumption, fast respond speed and high electron to photon conversion efficiency. Most of the organic light emitting diodes (OLEDs) are phosphorescent OLEDs using Iridium(Ir), palladium (Pd) and platinum (Pt) complexes, as these metal complexes have strong Spin-Orbital Coupling, they can efficiently emit light from their triplet exited state and reach nearly 100% internal efficiency.

Organic light-emitting diodes (OLEDs) have been widely considered as a key component for future display and lighting applications. It has been challenging to produce full color OLED displays for large area TVs due to the technical limitation of existing metal-based shadow masks, which results in a low production yield and a high manufacture expense. While the current industry is making OLED TV based on individually controlled white OLED pixels with color filters, such approach increases the complexity of manufacture process and increases power consumption for each OLED pixel. On the other hand, it has been suggested to fabricate large area full color displays with ink-jet printing techniques, which could circumvent the technical hurdle set by the shadow masks in the vapor-deposition process and produce more efficient OLED pixels in a potential low-cost fashion, making OLED TV more cost-competitive. However, the performance of solution processed OLED can't compete with vapor-deposited OLED more favorably, in terms of their efficiencies and device operational stabilities, due to the limited set of suitable materials and the lack of infrastructure support. Thus, more materials development efforts will be required for the ink-jet printing manufacture process to reach a wider market adoption.

There remains a need in the art for efficient and stable organic light-emitting diodes. This invention addresses this unmet need.

### SUMMARY OF THE INVENTION

Some embodiments of the invention disclosed herein are set forth below, and any combination of these embodiments (or portions thereof) may be made to define another embodiment.

In one aspect, the present disclosure relates to an organic light-emitting device, comprising: a first electrode;
an organic emissive layer disposed over the first electrode;
an electron transport layer disposed directly on the organic emissive layer; and a second electrode disposed over the electron transport layer;
wherein the electron transport layer has a thickness of less than 10 nm; and
wherein the electron transport layer comprises an aggregate material.

In some embodiments, the electron transport layer has a thickness of less than 5 nm. In some embodiments, the electron transport layer has a thickness of less than 3 nm. In some embodiments, the electron transport layer has a thickness of less than 1 nm.

In some embodiments, the organic light emitting device emits blue light. In some embodiments, the organic light-emitting device emits light of a first wavelength, wherein the first wavelength is between 450 nm and 550 nm. In some embodiments, the aggregate material has a first absorption coefficient over a first wavelength, wherein the first absorption coefficient is less than 0.1 cm⁻¹, and wherein the organic light-emitting device emits light of the first wavelength, wherein the first wavelength is from 450-550 nm. In some embodiments, the first absorption coefficient is less than 0.01 cm⁻¹. In some embodiments, the organic light emitting device further comprises an electron blocking layer disposed between the first electrode and the organic emissive layer.

In some embodiments, the organic emissive layer has a thickness less than 40 nm. In some embodiments, the organic emissive layer has a thickness greater than 15 nm. In some embodiments, the organic emissive layer comprises a first host material and a second host material; wherein the first host material is a p-type host; and wherein the second host material is an n-type host.

In some embodiments, wherein the electron transport layer further comprises a host material. In some embodiments, the electron transport layer consists of the aggregate material. In some embodiments, the aggregate material has a band gap larger than 2.5 eV. In some embodiments, the aggregate material comprises a metal complex. In some embodiments, the aggregate material comprises a Platinum (Pt) or Palladium (Pd) metal complex. In some embodiments, the aggregate material is a compound of General Formula I:

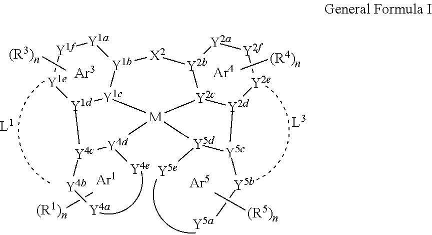

### In General Formula I:

M represents Pt(II) or Pd(II);
R¹, R³, R⁴, and R⁵ each independently represents hydrogen, halogen, hydroxyl, nitro, cyanide, thiol, or optionally substituted C₁-C₄ alkyl, alkoxy, amino, or aryl;
each n is independently an integer, valency permitting;
Y^{1a}, Y^{1b}, Y^{1c}, Y^{1d}, Y^{1e}, Y^{1f}, Y^{2a}, Y^{2b}, Y^{2c}, Y^{2d}, Y^{2e}, Y^{2f}, Y^{4a}, Y^{4b}, Y^{4c}, Y^{4d}, Y^{4e}, Y^{5a}, Y^{5b}, Y^{5c}, Y^{5d}, and Y^{5e} each independently represents C, N, Si, O, S;
X² represents NR, PR, CRR′, SiRR′, CRR′, SiRR′, O, S, S═O, O═S═O, Se, Se═O, or O═Se═O, where R and R′ each independently represents hydrogen, halogen, hydroxyl, nitro, cyanide, thiol, or optionally substituted C₁-C₄ alkyl, alkoxy, amino, aryl, or heteroaryl;
each of L¹ and L³ is independently present or absent, and if present, represents a substituted or unsubstituted linking atom or group, where a substituted linking atom is bonded to an alkyl, alkoxy, alkenyl, alkynyl, hydroxy, amine, amide, thiol, aryl, heteroaryl, cycloalkyl, or heterocyclyl moiety;
Ar³ and Ar⁴ each independently represents a 6-membered aryl group; and
Ar¹ and Ar⁵ each independently represents a 5- to 10-membered aryl, heteroaryl, fused aryl, or fused heteroaryl.

In some embodiments, the aggregate material is represented by General Formula II, General Formula III, General Formula IV, General Formula V, General Formula VI, General Formula VII, General Formula Vill, or General Formula IX:

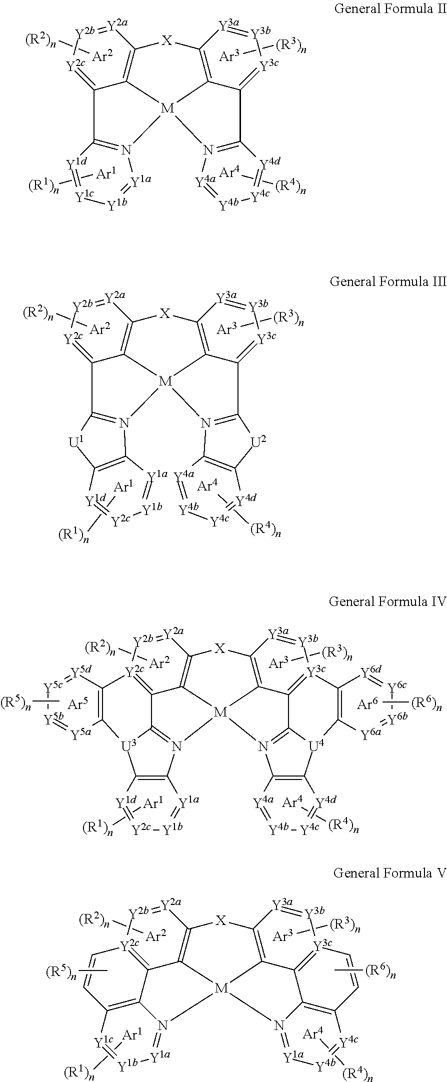

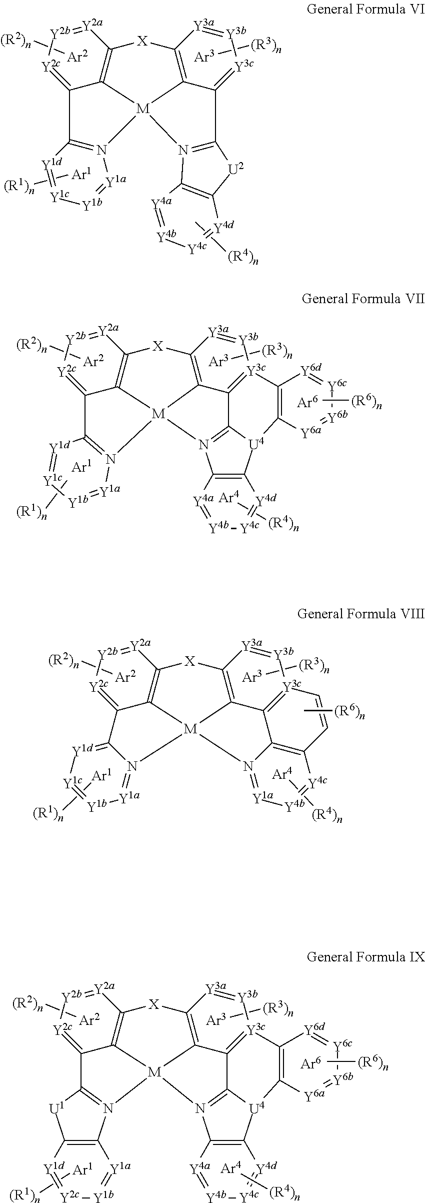

wherein, in General Formulas II-IX:
M represents Pt(II) or Pd(II);
R¹, R², R³, R⁴, R⁵, and R⁶ each independently represents hydrogen, halogen, hydroxyl, nitro, nitrile, thiol, or optionally substituted C₁-C₄ alkyl, alkoxy, amino, or aryl;
each n is independently an integer, valency permitting;
Y^{1a}, Y^{1b}, Y^{1c}, Y^{1d}, Y^{2a}, Y^{2b}, Y^{2c} Y^{3a}, Y^{3b}, Y^{3c}, Y^{4a}, Y^{4b}, Y^{4c}, Y^{5a}, Y^{5b}, Y^{5c}, Y^{5d}, Y^{6a}, Y^{6b}, Y^{6c}, and Y^{6d} each independently represents C, N, or Si;
U¹ and U² each independently represents NR, O or S, wherein R represents hydrogen, halogen, hydroxyl, nitro, nitrile, thiol, or optionally substituted C₁-C₄ alkyl, alkoxy, amino, or aryl;
U³ and U⁴ each independently represents N or P; and
X represents O, S, NR, CRR′, SiRR′, PR, BR, S═O, O═S═O, Se, Se═O, or O═Se═O, where R and R′ each independently represents hydrogen, halogen, hydroxyl, nitro, nitrile, thiol, or optionally substituted C₁-C₄ alkyl, alkoxy, amino, aryl, or heteroaryl.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 depicts a cross-sectional view of an exemplary OLED.

FIG. 2 depicts a schematic diagram of an OLED, where ETL is an electron transporting layer, EML is an emissive layer, and HTL is a hole transporting layer.

FIG. 3 depicts a schematic illustration of device operation in devices comprising amber aggregate and blue phosphorescent emissive layers.

FIG. 4 depicts exemplary chemical structures of Pd308-p (top left), PtON5-pdb-tbu (top right), SiBCz (bottom left), and SiTrzCz2 (bottom right).

FIGS. 5A-5D depict exemplary experimental results for experimental OLEDs.

FIGS. 6A-6D depict exemplary experimental results for experimental OLEDs.

FIGS. 7A-7F depict exemplary experimental results for experimental OLEDs.

FIGS. 8A-8G depict exemplary experimental results for experimental OLEDs.

FIGS. 9A-9D depict exemplary experimental results for experimental OLEDs.

FIGS. 10A-10F depict exemplary experimental results for experimental OLEDs.

FIGS. 11A-11F depict exemplary experimental results for experimental OLEDs.

FIG. 12 is a schematic illustration of device operation in exemplary blue phosphorescent devices with a 1-2 nm amber aggregate injection layer.

FIG. 13 is a schematic illustration of device operation in blue phosphorescent devices without a 1-2 nm amber aggregate injection layer.

FIG. 14A-14D depict exemplary experimental results for experimental devices 1-2 with the structure of 60 nm ITO/10 nm HATCN/60 nm NPD/5 nm SiBCz/EML/5 nm SiTrzCz2/40 nm 50 wt. % LG201: 50 wt. % Liq/2 nm Liq/100 nm Al, where EML is 10 wt. % PtON5-pdb-tbu: 60 wt. % SiBCz: 30 wt. % SiTrzCz2 25 nm for device 1, 10 wt. % PtON5-pdb-tbu: 60 wt. % SiBCz: 30 wt. % SiTrzCz2 25 nm/Pd308-py5 1 nm for device 2.

### DETAILED DESCRIPTION OF THE INVENTION

It is to be understood that the figures and descriptions of the present invention have been simplified to illustrate elements that are relevant for a clearer comprehension of the present invention, while eliminating, for the purpose of clarity, many other elements found in efficient and stable all phosphorescent white organic light emitting diodes with excellent color stability. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, 10%, 5%, 1%, or +0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the invention. Thus, if there are a variety of additional steps that can be performed it is understood that each of these additional steps can be performed with any specific embodiment or combination of embodiments of the methods of the invention.

As referred to herein, a linking atom or a linking group can connect two groups such as, for example, an N and C group. The linking atom can optionally, if valency permits, have other chemical moieties attached. For example, in one aspect, an oxygen would not have any other chemical groups attached as the valency is satisfied once it is bonded to two groups (e.g., N and/or C groups). In another aspect, when carbon is the linking atom, two additional chemical moieties can be attached to the carbon. Suitable chemical moieties include, but are not limited to, hydrogen, hydroxyl, alkyl, alkoxy, ═O, halogen, nitro, amine, amide, thiol, aryl, heteroaryl, cycloalkyl, and heterocyclyl.

The term “cyclic structure” or the like terms used herein refer to any cyclic chemical structure which includes, but is not limited to, aryl, heteroaryl, cycloalkyl, cycloalkenyl, and heterocyclyl.

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valences of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc. It is also contemplated that, in certain aspects, unless expressly indicated to the contrary, individual substituents can be further optionally substituted (i.e., further substituted or unsubstituted).

The term “alkyl” as used herein is a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic or acyclic. The alkyl group can be branched or unbranched. The alkyl group can also be substituted or unsubstituted. For example, the alkyl group can be substituted with one or more groups including, but not limited to, alkyl, cycloalkyl, alkoxy, amino, ether, halide, hydroxy, nitro, silyl, sulfo-oxo, or thiol, as described herein. A “lower alkyl” group is an alkyl group containing from one to six (e.g., from one to four) carbon atoms.

Throughout the specification “alkyl” is generally used to refer to both unsubstituted alkyl groups and substituted alkyl groups; however, substituted alkyl groups are also specifically referred to herein by identifying the specific substituent(s) on the alkyl group. For example, the term “halogenated alkyl” or “haloalkyl” specifically refers to an alkyl group that is substituted with one or more halide, e.g., fluorine, chlorine, bromine, or iodine. The term “alkoxyalkyl” specifically refers to an alkyl group that is substituted with one or more alkoxy groups, as described below. The term “alkylamino” specifically refers to an alkyl group that is substituted with one or more amino groups, as described below, and the like. When “alkyl” is used in one instance and a specific term such as “alkylalcohol” is used in another, it is not meant to imply that the term “alkyl” does not also refer to specific terms such as “alkylalcohol” and the like.

This practice is also used for other groups described herein. That is, while a term such as “cycloalkyl” refers to both unsubstituted and substituted cycloalkyl moieties, the substituted moieties can, in addition, be specifically identified herein; for example, a particular substituted cycloalkyl can be referred to as, e.g., an “alkylcycloalkyl.” Similarly, a substituted alkoxy can be specifically referred to as, e.g., a “halogenated alkoxy,” a particular substituted alkenyl can be, e.g., an “alkenylalcohol,” and the like. Again, the practice of using a general term, such as “cycloalkyl,” and a specific term, such as “alkylcycloalkyl,” is not meant to imply that the general term does not also include the specific term.

The term “cycloalkyl” as used herein is a non-aromatic carbon-based ring composed of at least three carbon atoms. Examples of cycloalkyl groups include, but are not limited to, cyclopropyl, cyclobutyl, cyclopentyl, cyclohexyl, norbornyl, and the like. The term “heterocycloalkyl” is a type of cycloalkyl group as defined above, and is included within the meaning of the term “cycloalkyl,” where at least one of the carbon atoms of the ring is replaced with a heteroatom such as, but not limited to, nitrogen, oxygen, sulfur, or phosphorus. The cycloalkyl group and heterocycloalkyl group can be substituted or unsubstituted. The cycloalkyl group and heterocycloalkyl group can be substituted with one or more groups including, but not limited to, alkyl, cycloalkyl, alkoxy, amino, ether, halide, hydroxy, nitro, silyl, sulfo-oxo, or thiol as described herein.

The term “polyalkylene group” as used herein is a group having two or more CH₂ groups linked to one another. The polyalkylene group can be represented by the formula —(CH₂)ₐ—, where “a” is an integer of from 2 to 500.

The terms “alkoxy” and “alkoxyl” as used herein to refer to an alkyl or cycloalkyl group bonded through an ether linkage; that is, an “alkoxy” group can be defined as —OA¹ where A¹ is alkyl or cycloalkyl as defined above. “Alkoxy” also includes polymers of alkoxy groups as just described; that is, an alkoxy can be a polyether such as —OA¹-OA² or -OA¹-(OA²)ₐ-OA³, where “a” is an integer of from 1 to 200 and A¹, A², and A³ are alkyl and/or cycloalkyl groups.

The term “alkenyl” as used herein is a hydrocarbon group of from 2 to 24 carbon atoms with a structural formula containing at least one carbon-carbon double bond. Asymmetric structures such as (A¹A²)C═C(A³A⁴) are intended to include both the E and Z isomers. This can be presumed in structural formulae herein wherein an asymmetric alkene is present, or it can be explicitly indicated by the bond symbol C═C. The alkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkenyl” as used herein is a non-aromatic carbon-based ring composed of at least three carbon atoms and containing at least one carbon-carbon double bond, i.e., C═C. Examples of cycloalkenyl groups include, but are not limited to, cyclopropenyl, cyclobutenyl, cyclopentenyl, cyclopentadienyl, cyclohexenyl, cyclohexadienyl, norbornenyl, and the like. The term “heterocycloalkenyl” is a type of cycloalkenyl group as defined above, and is included within the meaning of the term “cycloalkenyl,” where at least one of the carbon atoms of the ring is replaced with a heteroatom such as, but not limited to, nitrogen, oxygen, sulfur, or phosphorus. The cycloalkenyl group and heterocycloalkenyl group can be substituted or unsubstituted. The cycloalkenyl group and heterocycloalkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “alkynyl” as used herein is a hydrocarbon group of 2 to 24 carbon atoms with a structural formula containing at least one carbon-carbon triple bond. The alkynyl group can be unsubstituted or substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkynyl” as used herein is a non-aromatic carbon-based ring composed of at least seven carbon atoms and containing at least one carbon-carbon triple bound. Examples of cycloalkynyl groups include, but are not limited to, cycloheptynyl, cyclooctynyl, cyclononynyl, and the like. The term “heterocycloalkynyl” is a type of cycloalkenyl group as defined above, and is included within the meaning of the term “cycloalkynyl,” where at least one of the carbon atoms of the ring is replaced with a heteroatom such as, but not limited to, nitrogen, oxygen, sulfur, or phosphorus. The cycloalkynyl group and heterocycloalkynyl group can be substituted or unsubstituted. The cycloalkynyl group and heterocycloalkynyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “aryl” as used herein is a group that contains any carbon-based aromatic group including, but not limited to, benzene, naphthalene, phenyl, biphenyl, phenoxybenzene, and the like. The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group is optionally substituted.

The term “aryl” also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term “non-heteroaryl,” which is also included in the term “aryl,” defines a group that contains an aromatic group that does not contain a heteroatom. The aryl group can be substituted or unsubstituted. The aryl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein. The term “biaryl” is a specific type of aryl group and is included in the definition of “aryl.” Biaryl refers to two aryl groups that are bound together via a fused ring structure, as in naphthalene, or are attached via one or more carbon-carbon bonds, as in biphenyl.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group is optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

The term “aldehyde” as used herein is represented by the formula —C(O)H. Throughout this specification “C(O)” is a short hand notation for a carbonyl group, i.e., C═O.

The terms “amine” or “amino” as used herein are represented by the formula —NA¹A², where A¹ and A² can be, independently, hydrogen or alkyl, cycloalkyl, alkenyl, cycloalkenyl, alkynyl, cycloalkynyl, aryl, or heteroaryl group as described herein.

The term “alkylamino” as used herein is represented by the formula —NH(-alkyl) where alkyl is a described herein. Representative examples include, but are not limited to, methylamino group, ethylamino group, propylamino group, isopropylamino group, butylamino group, isobutylamino group, (sec-butyl)amino group, (tert-butyl)amino group, pentylamino group, isopentylamino group, (tert-pentyl)amino group, hexylamino group, and the like.

The term “dialkylamino” as used herein is represented by the formula —N(-alkyl)₂ where alkyl is a described herein. Representative examples include, but are not limited to, dimethylamino group, diethylamino group, dipropylamino group, diisopropylamino group, dibutylamino group, diisobutylamino group, di(sec-butyl)amino group, di(tert-butyl)amino group, dipentylamino group, diisopentylamino group, di(tert-pentyl)amino group, dihexylamino group, N-ethyl-N-methylamino group, N-methyl-N-propylamino group, N-ethyl-N-propylamino group and the like.

The term “carboxylic acid” as used herein is represented by the formula —C(O)OH.

The term “ester” as used herein is represented by the formula —OC(O)A¹ or —C(O)OA¹, where A¹ can be alkyl, cycloalkyl, alkenyl, cycloalkenyl, alkynyl, cycloalkynyl, aryl, or heteroaryl group as described herein. The term “polyester” as used herein is represented by the formula -(A¹O(O)C-A²-C(O)O), or -(A¹O(O)C-A²-OC(O))ₐ—, where Aland A² can be, independently, an alkyl, cycloalkyl, alkenyl, cycloalkenyl, alkynyl, cycloalkynyl, aryl, or heteroaryl group described herein and “a” is an integer from 1 to 500. “Polyester” is as the term used to describe a group that is produced by the reaction between a compound having at least two carboxylic acid groups with a compound having at least two hydroxyl groups.

The term “ether” as used herein is represented by the formula A¹OA², where Aland A² can be, independently, an alkyl, cycloalkyl, alkenyl, cycloalkenyl, alkynyl, cycloalkynyl, aryl, or heteroaryl group described herein. The term “polyether” as used herein is represented by the formula -(A¹O-A²O)ₐ—, where A¹ and A² can be, independently, an alkyl, cycloalkyl, alkenyl, cycloalkenyl, alkynyl, cycloalkynyl, aryl, or heteroaryl group described herein and “a” is an integer of from 1 to 500. Examples of polyether groups include polyethylene oxide, polypropylene oxide, and polybutylene oxide.

The term “halide” as used herein refers to the halogens fluorine, chlorine, bromine, and iodine.

The term “heterocyclyl,” as used herein refers to single and multi-cyclic non-aromatic ring systems and “heteroaryl” as used herein refers to single and multi-cyclic aromatic ring systems: in which at least one of the ring members is other than carbon. The term “heterocyclyl” includes azetidine, dioxane, furan, imidazole, isothiazole, isoxazole, morpholine, oxazole, oxazole, including, 1,2,3-oxadiazole, 1,2,5-oxadiazole and 1,3,4-oxadiazole, piperazine, piperidine, pyrazine, pyrazole, pyridazine, pyridine, pyrimidine, pyrrole, pyrrolidine, tetrahydrofuran, tetrahydropyran, tetrazine, including 1,2,4,5-tetrazine, tetrazole, including 1,2,3,4-tetrazole and 1,2,4,5-tetrazole, thiadiazole, including, 1,2,3-thiadiazole, 1,2,5-thiadiazole, and 1,3,4-thiadiazole, thiazole, thiophene, triazine, including 1,3,5-triazine and 1,2,4-triazine, triazole, including, 1,2,3-triazole, 1,3,4-triazole, and the like.

The term “hydroxyl” as used herein is represented by the formula —OH.

The term “ketone” as used herein is represented by the formula A¹C(O)A², where Aland A² can be, independently, an alkyl, cycloalkyl, alkenyl, cycloalkenyl, alkynyl, cycloalkynyl, aryl, or heteroaryl group as described herein.

The term “azide” as used herein is represented by the formula —N3.

The term “nitro” as used herein is represented by the formula —NO₂.

The term “nitrile” as used herein is represented by the formula —CN.

The term “ureido” as used herein refers to a urea group of the formula —NHC(O)NH₂ or —NHC(O)NH—.

The term “phosphoramide” as used herein refers to a group of the formula —P(O)(NA¹A²)₂, where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “carbamoyl” as used herein refers to an amide group of the formula —CONA¹A², where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “sulfamoyl” as used herein refers to a group of the formula —S(O)₂NA¹A², where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “silyl” as used herein is represented by the formula -SiA1A²A³, where A¹, A², and A³ can be, independently, hydrogen or an alkyl, cycloalkyl, alkoxy, alkenyl, cycloalkenyl, alkynyl, cycloalkynyl, aryl, or heteroaryl group as described herein.

The term “sulfo-oxo” as used herein is represented by the formulas —S(O)A¹, —S(O)₂A¹, —OS(O)₂A¹, or —OS(O)₂OA¹, where A¹ is hydrogen or an alkyl, cycloalkyl, alkenyl, cycloalkenyl, alkynyl, cycloalkynyl, aryl, or heteroaryl group as described herein. Throughout this specification “S(O)” is a short hand notation for S═O. The term “sulfonyl” is used herein to refer to the sulfo-oxo group represented by the formula —S(O)₂A¹, where A¹ is hydrogen or an alkyl, cycloalkyl, alkenyl, cycloalkenyl, alkynyl, cycloalkynyl, aryl, or heteroaryl group as described herein. The term “sulfone” as used herein is represented by the formula A¹S(O)₂A², where A¹ and A² can be, independently, an alkyl, cycloalkyl, alkenyl, cycloalkenyl, alkynyl, cycloalkynyl, aryl, or heteroaryl group as described herein. The term “sulfoxide” as used herein is represented by the formula A¹S(O)A², where A¹ and A² can be, independently, an alkyl, cycloalkyl, alkenyl, cycloalkenyl, alkynyl, cycloalkynyl, aryl, or heteroaryl group as described herein.

The term “thiol” as used herein is represented by the formula —SH.

The term “polymeric” includes polyalkylene, polyether, polyester, and other groups with repeating units, such as, but not limited to —(CH₂O)ₙ—CH₃, —(CH₂CH₂O)ₙ—CH₃, —[CH₂CH(CH₃)]ₙ—CH₃, —[CH₂CH(COOCH₃)]ₙ—CH₃, —[CH₂CH(COOCH₂CH₃)]ₙ—CH₃, and —[CH₂CH(COO^{t}Bu)]ₙ—CH₃, where n is an integer (e.g., n>1 or n>2).

“R,” “R¹,” “R²,” “R³,” “Rⁿ,” where n is an integer, as used herein can, independently, include hydrogen or one or more of the groups listed above. For example, if R¹ is a straight chain alkyl group, one of the hydrogen atoms of the alkyl group can optionally be substituted with a hydroxyl group, an alkoxy group, an alkyl group, a halide, and the like. Depending upon the groups that are selected, a first group can be incorporated within a second group or, alternatively, the first group can be pendant (i.e., attached) to the second group. For example, with the phrase “an alkyl group comprising an amino group,” the amino group can be incorporated within the backbone of the alkyl group. Alternatively, the amino group can be attached to the backbone of the alkyl group. The nature of the group(s) that is (are) selected will determine if the first group is embedded or attached to the second group.

As described herein, compounds of the disclosure may contain “optionally substituted” moieties. In general, the term “substituted,” whether preceded by the term “optionally” or not, means that one or more hydrogens of the designated moiety are replaced with a suitable substituent. Unless otherwise indicated, an “optionally substituted” group may have a suitable substituent at each substitutable position of the group, and when more than one position in any given structure may be substituted with more than one substituent selected from a specified group, the substituent may be either the same or different at every position. Combinations of substituents envisioned by this disclosure are preferably those that result in the formation of stable or chemically feasible compounds. It is also contemplated that, in certain aspects, unless expressly indicated to the contrary, individual substituents can be further optionally substituted (i.e., further substituted or unsubstituted).

In some instances, a pair of adjacent substituents can be optionally joined or fused into a ring. The preferred ring is a five, six, or seven-membered carbocyclic or heterocyclic ring, which includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

In some aspects, a structure of a compound can be represented by a formula:

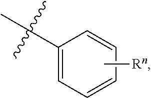

which is understood to be equivalent to a formula:

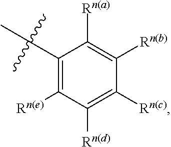

wherein n is typically an integer. That is, Rⁿ is understood to represent five independent substituents, R^{n(a)}, R^{n(b)}, R^{n(c)}, R^{n(d)}, R^{n(e)}. By “independent substituents,” it is meant that each R substituent can be independently defined. For example, if in one instance Rⁿ(a) is halogen, then Rⁿ(b) is not necessarily halogen in that instance.

Several references to R, R¹, R², R³, R⁴, R⁵, R⁶, etc. are made in chemical structures and moieties disclosed and described herein. Any description of R, R¹, R², R³, R⁴, R⁵, R⁶, etc. in the specification is applicable to any structure or moiety reciting R, R¹, R², R³, R⁴, R⁵, R⁶, etc. respectively.

Compounds disclosed herein are suited for use in a wide variety of optical and electro-optical devices, including, but not limited to, photo-absorbing devices such as solar- and photo-sensitive devices, organic light emitting devices (OLEDs), photo-emitting devices, or devices capable of both photo-absorption and emission and as markers for bio-applications.

The compounds disclosed herein are useful in a variety of applications. As light emitting materials, the compounds can be useful in organic light emitting devices (OLEDs), luminescent devices and displays, and other light emitting devices.

In another aspect, the compounds can provide improved efficiency, improved operational lifetimes, or both in lighting devices, such as, for example, organic light emitting devices, as compared to conventional materials.

The compounds of the disclosure can be made using a variety of methods, including, but not limited to any recited in the examples provided herein.

In one aspect, the device is an electro-optical device. Electro-optical devices include, but are not limited to, photo-absorbing devices such as solar- and photo-sensitive devices, organic light emitting devices, photo-emitting devices, or devices capable of both photo-absorption and emission and as markers for bio-applications. For example, the device can be an OLED.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art. Such devices are disclosed herein which comprise one or more of the compounds or compositions disclosed herein.

In one embodiment, the device is a white OLED. In one embodiment, the device emits amber light and blue light, which when combined is received as white light. In one embodiment, the color (i.e., warmth) of the white light can be adjusted by varying the thickness and concentration of the various emissive layers.

OLEDs can be produced by methods known to those skilled in the art. In general, the OLED is produced by successive vapor deposition of the individual layers onto a suitable substrate. Suitable substrates include, for example, glass, inorganic materials such as ITO or IZO or polymer films. For the vapor deposition, customary techniques may be used, such as thermal evaporation, chemical vapor deposition (CVD), physical vapor deposition (PVD) and others.

In an alternative process, the organic layers may be coated from solutions or dispersions in suitable solvents, in which case coating techniques known to those skilled in the art are employed. Suitable coating techniques are, for example, spin-coating, the casting method, the Langmuir-Blodgett (“LB”) method, the inkjet printing method, dip-coating, letterpress printing, screen printing, doctor blade printing, slit-coating, roller printing, reverse roller printing, offset lithography printing, flexographic printing, web printing, spray coating, coating by a brush or pad printing, and the like. Among the processes mentioned, in addition to the aforementioned vapor deposition, preference is given to spin-coating, the inkjet printing method and the casting method since they are particularly simple and inexpensive to perform. In the case that layers of the OLED are obtained by the spin-coating method, the casting method or the inkjet printing method, the coating can be obtained using a solution prepared by dissolving the composition in a concentration of 0.0001 to 90% by weight in a suitable organic solvent such as benzene, toluene, xylene, tetrahydrofuran, methyltetrahydrofuran, N,N-dimethylformamide, acetone, acetonitrile, anisole, dichloromethane, dimethyl sulfoxide, water and mixtures thereof.

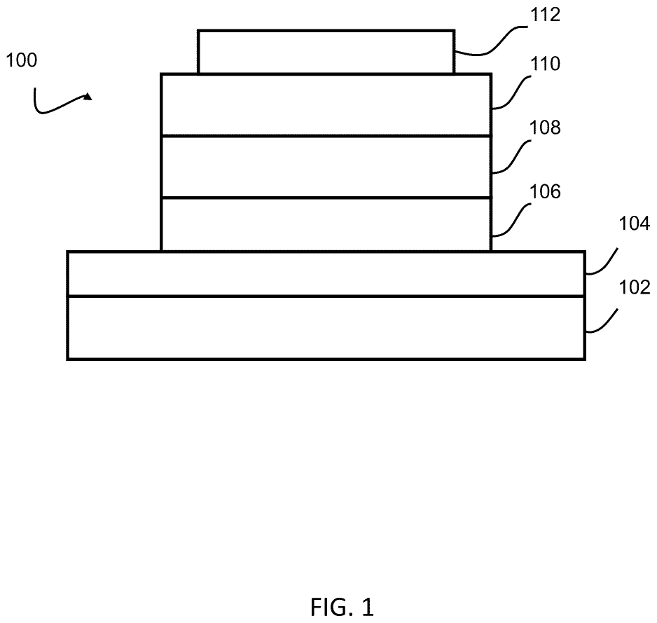

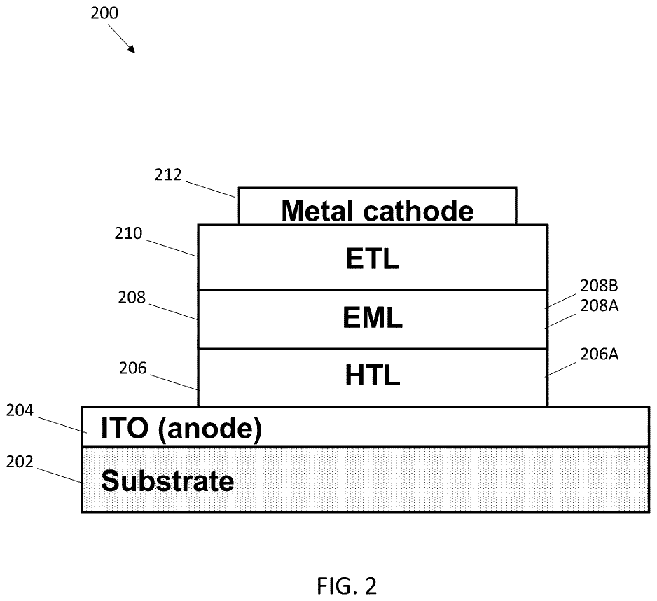

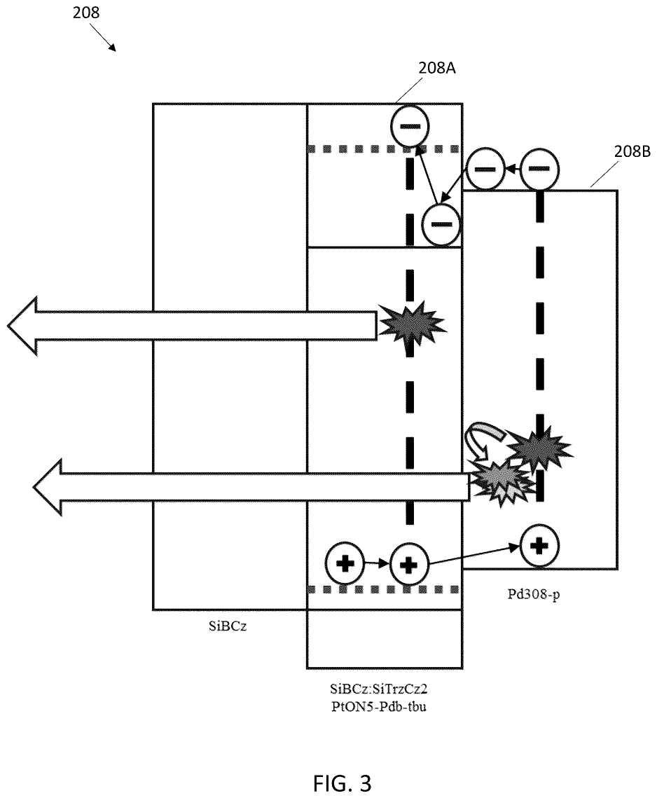

Compounds described herein can be used in a light emitting device such as an OLED. FIG. 1 depicts a cross-sectional view of an OLED 100. OLED 100 includes substrate 102, anode 104, electron-transporting material(s) (ETL) 106, light processing material 108, hole-transporting material(s) (HTL) 110, and a metal cathode layer 112. Anode 104 is typically a transparent material, such as indium tin oxide. Light processing material 108 may be an emissive material (EML) including an emitter and a host.

In various aspects, any of the one or more layers depicted in FIG. 1 may include indium tin oxide (ITO), poly(3,4-ethylenedioxythiophene) (PEDOT), polystyrene sulfonate (PSS), N,N′-di-1-naphthyl-N,N-diphenyl-1,1′-biphenyl-4,4′ diamine (NPD), 1,1-bis((di-4-tolylamino)phenyl)cyclohexane (TAPC), 2,6-Bis(N-carbazolyl)pyridine (mCpy), 2,8-bis(diphenylphosphoryl)dibenzothiophene (PO15), LiF, Al, or a combination thereof.

Light processing material 108 may include one or more compounds of the present disclosure optionally together with a host material. The host material can be any suitable host material known in the art. The emission color of an OLED is determined by the emission energy (optical energy gap) of the light processing material 108, which can be tuned by tuning the electronic structure of the emitting compounds, the host material, or both. Both the hole-transporting material in the HTL layer 110 and the electron-transporting material(s) in the ETL layer 106 may include any suitable hole-transporter known in the art.

Compounds described herein may exhibit phosphorescence. Phosphorescent OLEDs (i.e., OLEDs with phosphorescent emitters) typically have higher device efficiencies than other OLEDs, such as fluorescent OLEDs. Light emitting devices based on electrophosphorescent emitters are described in more detail in WO2000/070655 to Baldo et al., which is incorporated herein by this reference for its teaching of OLEDs, and in particular phosphorescent OLEDs.

As contemplated herein, an OLED of the present invention may include an anode, a cathode, and an organic layer disposed between the anode and the cathode. The organic layer may include a host and a phosphorescent dopant. The organic layer can include a compound of the invention and its variations as described herein.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In one embodiment, the invention relates to a consumer product comprising a device described herein. Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, a light therapy device, and a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.), but could be used outside this temperature range, for example, from −40 degree c. to +80 degree C.

In one embodiment, the consumer product is selected from the group consisting of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, and a sign.

In some embodiments of the emissive region, the emissive region further comprises a host, wherein the host comprises at least one selected from the group consisting of metal complex, triphenylene, carbazole, dibenzothiophene, dibenzofuran, dibenzoselenophene, aza-triphenylene, aza-carbazole, aza-dibenzothiophene, aza-dibenzofuran, and aza-dibenzoselenophene.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be a triphenylene containing benzo-fused thiophene or benzo-fused furan. Any substituent in the host can be an unfused substituent independently selected from the group consisting of CₙH₂ₙ₊₁, OCₙH₂ₙ₊₁, OAr₁, N(CₙH₂ₙ₊₁)₂, N(Ar₁)(Ar₂), CH═CH—CₙH₂ₙ₊₁, C≡C—CₙH₂ₙ₊₁, Ar₁, Ar₁—Ar₂, and CₙH₂ₙ—Ar₁, or the host has no substitutions. In the preceding substituents n can range from 1 to 10; and Ar1 and Ar2 can be independently selected from the group consisting of benzene, biphenyl, naphthalene, triphenylene, carbazole, and heteroaromatic analogs thereof. The host can be an inorganic compound. For example, a Zn containing inorganic material e.g. ZnS.

In one aspect, the host compound contains at least one of the following groups selected from the group consisting of aromatic hydrocarbon cyclic compounds such as benzene, biphenyl, triphenyl, triphenylene, tetraphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each option within each group may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

Additional suitable hosts include, but are not limited to, mCP (1,3-bis(carbazol-9-yl)benzene), mCPy (2,6-bis(N-carbazolyl)pyridine), TCP (1,3,5-tris(carbazol-9-yl)benzene), TCTA (4,4′,4″-tris(carbazol-9-yl)triphenylamine), TPBi (1,3,5-tris(1-phenyl-1-H-benzimidazol-2-yl)benzene), mCBP (3,3-di(9H-carbazol-9-yl)biphenyl), pCBP (4,4′-bis(carbazol-9-yl)biphenyl), CDBP (4,4′-bis(9-carbazolyl)-2,2′-dimethylbiphenyl), Tris-PCz (9-Phenyl-3,6-bis(9-phenyl-9H-carbazol-3-yl)-9H-carbazole), DMFL-CBP (4,4′-bis(carbazol-9-yl)-9,9-dimethylfluorene), FL-4CBP (4,4′-bis(carbazol-9-yl)-9,9-bis(9-phenyl-9H-carbazole)fluorene), FL-2CBP (9,9-bis(4-carbazol-9-yl)phenyl)fluorene, also abbreviated as CPF), DPFL-CBP (4,4′-bis(carbazol-9-yl)-9,9-ditolylfluorene), FL-2CBP (9,9-bis(9-phenyl-9H-carbazole)fluorene), Spiro-CBP (2,2′,7,7′-tetrakis(carbazol-9-yl)-9,9′-spirobifluorene), ADN (9,10-di(naphth-2-yl)anthracene), TBADN (3-tert-butyl-9,10-di(naphth-2-yl)anthracene), DPVBi (4,4′-bis(2,2-diphenylethen-1-yl)-4,4′-dimethylphenyl), p-DMDPVBi (4,4′-bis(2,2-diphenylethen-1-yl)-4,4′-dimethylphenyl), TDAF (tert(9,9-diarylfluorene)), BSBF (2-(9,9′-spirobifluoren-2-yl)-9,9′-spirobifluorene), TSBF (2,7-bis(9,9′-spirobifluoren-2-yl)-9,9′-spirobifluorene), BDAF (bis(9,9-diarylfluorene)), p-TDPVBi (4,4′-bis(2,2-diphenylethen-1-yl)-4,4′-di-(tert-butyl)phenyl), TPB3 (1,3,5-tri(pyren-1-yl)benzene, PBD (2-(4-biphenylyl)-5-(4-tert-butylphenyl)-1,3,4-oxadiazole), BCP (2,9-dimethyl-4,7-diphenyl-1,10-phenanthroline), BP-OXD-Bpy (6,6′-bis[5-(biphenyl-4-yl)-1,3,4-oxadiazo-2-yl]-2,2′-bipyridyl), NTAZ (4-(naphth-1-yl)-3,5-diphenyl-4H-1,2,4-triazole), Bpy-OXD (1,3-bis[2-(2,2′-bipyrid-6-yl)-1,3,4oxadiazo-5-yl]benzene), BPhen (4,7-diphenyl-1,10-phenanthroline), TAZ (3-(4-biphenylyl)-4-phenyl-5-tert-butylphenyl-1,2,4-triazole), PADN (2-phenyl-9,10-di(naphth-2-yl)anthracene), Bpy-FOXD (2,7-bis[2-(2,2′-bipyrid-6-yl)-1,3,4-oxadiazol-5-yl]-9,9-dimethylfluorene), OXD-7 (1,3-bis[2-(4-tert-butylphenyl)-1,3,4-oxadiazol-5-yl]benzene), HNBphen (2-(naphth-2-yl)-4,7-diphenyl-1,10-phenanthroline), NBphen (2,9-bis(naphth-2-yl)-4,7-diphenyl-1,10-phenanthroline), 3TPYMB (tris(2,4,6-trimethyl-3-(pyrid-3-yl)phenyl)borane), 2-NPIP (1-methyl-2-(4-(naphth-2-yl)phenyl)-1H-imidazo[4,5-f]-[1,10]phenanthroline), Liq (8-hydroxyquinolinolatolithium), and Alq (bis(2-methyl-8-quinolinolate)-4-(phenylphenolato)aluminum), and also of mixtures of the aforesaid substances.

The present disclosure encompasses any chemical structure comprising the novel compound of the present disclosure, or a monovalent or polyvalent variant thereof. In other words, the inventive compound, or a monovalent or polyvalent variant thereof, can be a part of a larger chemical structure. Such chemical structure can be selected from the group consisting of a monomer, a polymer, a macromolecule, and a supramolecule (also known as supermolecule). As used herein, a “monovalent variant of a compound” refers to a moiety that is identical to the compound except that one hydrogen has been removed and replaced with a bond to the rest of the chemical structure. As used herein, a “polyvalent variant of a compound” refers to a moiety that is identical to the compound except that more than one hydrogen has been removed and replaced with a bond or bonds to the rest of the chemical structure. In the instance of a supramolecule, the inventive compound can also be incorporated into the supramolecule complex without covalent bonds.

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

Non-limiting examples of the conductivity dopants that may be used in an OLED in combination with materials disclosed herein are exemplified in references that disclose those materials: EP01617493, EP01968131, EP2020694, EP2684932, US20050139810, US20070160905, US20090167167, US2010288362, WO06081780, WO2009003455, WO2009008277, WO2009011327, WO2014009310, US2007252140, US2015060804, US20150123047, and US2012146012.

A hole injecting/transporting material to be used in the present invention is not particularly limited, and any compound may be used as long as the compound is typically used as a hole injecting/transporting material. Examples of the material include, but are not limited to: a phthalocyanine or porphyrin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and silane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and/or higher triplet energy than one or more of the hosts closest to the EBL interface. In one aspect, the compound used in EBL contains the same molecule or the same functional groups used as one of the hosts described below.

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

An emitter example is not particularly limited, and any compound may be used as long as the compound is typically used as an emitter material. Examples of suitable emitter materials include, but are not limited to, compounds which can produce emissions via phosphorescence, fluorescence, thermally activated delayed fluorescence, i.e., TADF (also referred to as E-type delayed fluorescence; see, e.g., U.S. application Ser. No. 15/700,352, which is hereby incorporated by reference in its entirety), triplet-triplet annihilation, metal-assisted delayed fluorescence (MADF), or combinations of these processes. In some embodiments, the emissive dopant can be a racemic mixture, or can be enriched in one enantiomer.

One or more additional emitter dopants may be used in conjunction with the compound of the present disclosure. Examples of the additional emitter dopants are not particularly limited, and any compounds may be used as long as the compounds are typically used as emitter materials. Examples of suitable emitter materials include, but are not limited to, compounds which can produce emissions via phosphorescence, fluorescence, thermally activated delayed fluorescence, i.e., TADF (also referred to as E-type delayed fluorescence), triplet-triplet annihilation, or combinations of these processes.

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and/or higher triplet energy than the emitter closest to the HBL interface. In some embodiments, the HBL material has a lower HOMO (further from the vacuum level) and/or higher triplet energy than one or more of the hosts closest to the HBL interface.

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

In any above-mentioned compounds used in each layer of the OLED device, the hydrogen atoms can be partially or fully deuterated. Thus, any specifically listed substituent, such as, without limitation, methyl, phenyl, pyridyl, etc. may be undeuterated, partially deuterated, and fully deuterated versions thereof. Similarly, classes of substituents such as, without limitation, alkyl, aryl, cycloalkyl, heteroaryl, etc. also may be undeuterated, partially deuterated, and fully deuterated versions thereof.

In yet another aspect of the present disclosure, a formulation that comprises the novel compound disclosed herein is described. The formulation can include one or more components selected from the group consisting of a solvent, a host, a hole injection material, hole transport material, and an electron transport layer material, disclosed herein.

Organic light emitting device (OLED) are a new generation of display technology. An example typical OLED device includes a layer of indium tin oxide as an anode, a single layer of hole-transporting materials (HTL), a single layer of emissive materials (EML) including emitter and host, a single layer of electron-transporting materials (ETL) and a layer of metal cathode. The emission color of OLED is determined by the emission energy (optical energy gap) of emitters. Phosphorescent OLEDs (i.e. phosphorescent materials as emitters) have higher device efficiency than that of fluorescent OLEDs (i.e. fluorescent materials as emitters).

White organic light emitting diodes (WOLEDs) are potentially viable candidates for use in solid-state lighting and backlighting applications for tunable color. The adoption of WOLEDs is generally limited by the lack of simultaneous demonstration of high external quantum efficiency (EQE), balanced color quality, long operational lifetime, and color stability under various driving currents. While high EQE, balanced color quality, and long operational lifetimes have been achieved before, reasonable color stability is seldom reported. The main barrier to color stability under various driving current lies in how white color is realized in WOLEDs where red, green, and blue emissive layers or blue and orange emissive layers are combined to generate broad white light emission. When having multiple emissive layers, the color can shift at varied current densities due to recombination zone movement or due to changes in energy transfer processes. Tandem WOLEDs have reduced this issue by separating the emissive layers, however this comes at a prohibitive manufacturing cost due to the increased device complexity. Previously, researchers have demonstrated good EQE, lifetime, and color stability through the use of an orange phosphorescent aggregate emitter and blue fluorescent emitter, however the relatively limited efficiency of the blue fluorescent emitter made it so balanced color could not be achieved in these devices while maintaining high device performance (see U.S. patent application Ser. Nos. 16/756,219, 16/756,226, 15/503,690, 17/038,402, 17/347,716, and 18/054,209, each incorporated by reference in their entirety). Therefore, it is necessary to find a new device structure that utilizes an orange phosphorescent aggregate emitter and a blue phosphorescent emitter.

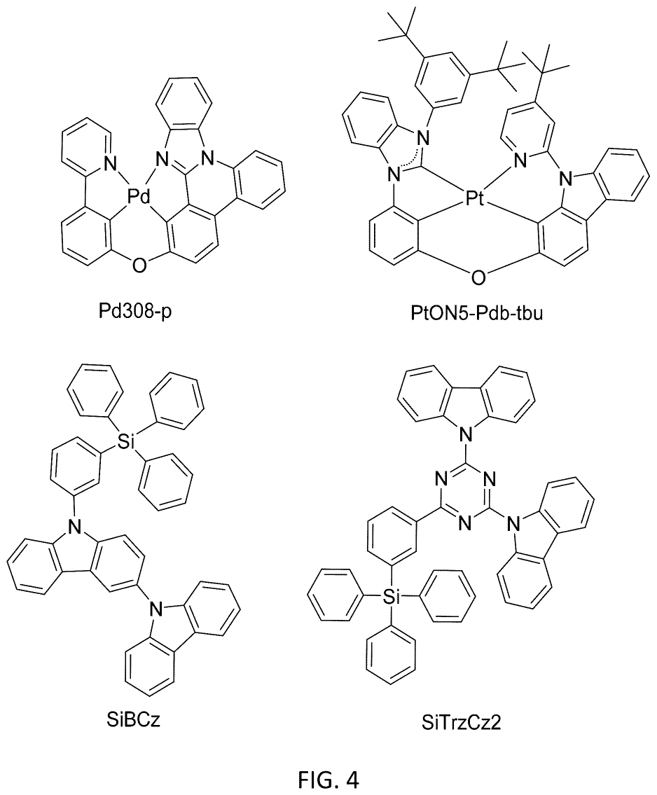

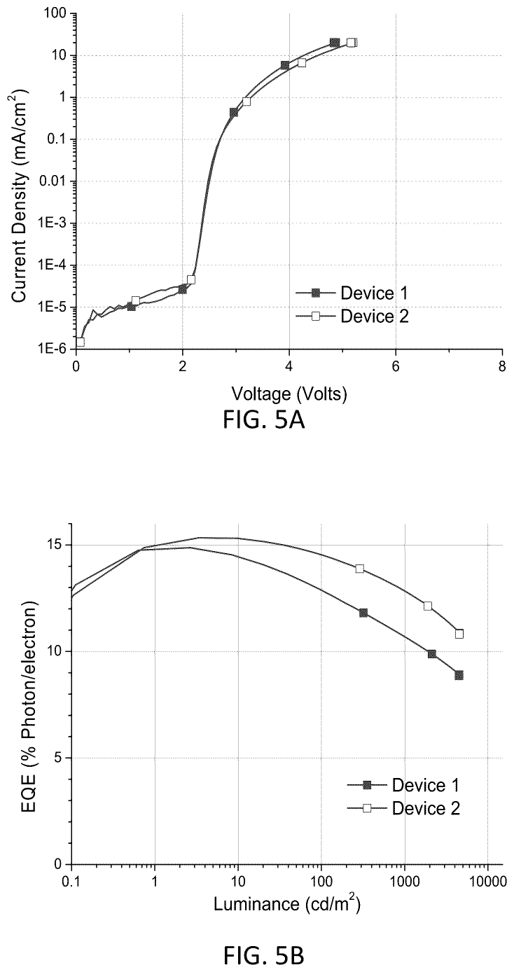

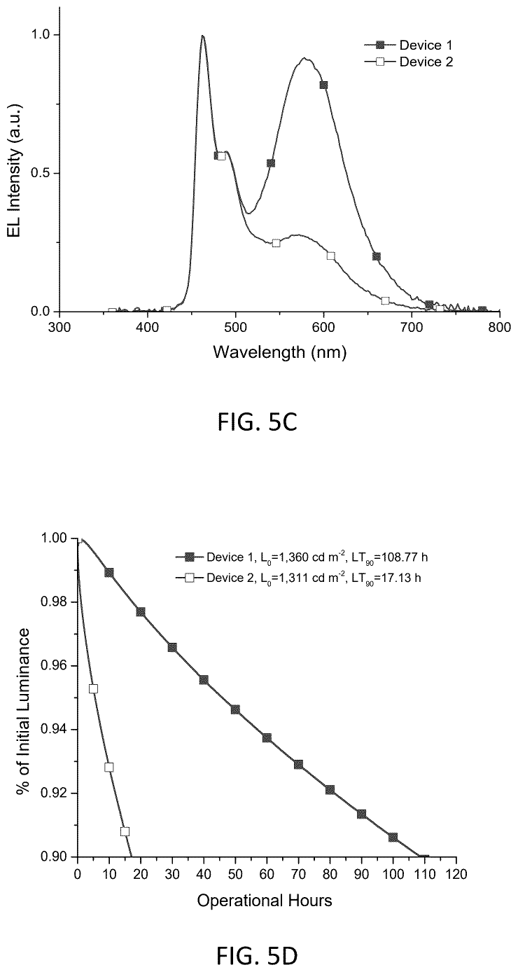

The disclosed devices are based on the usage of an orange-emitting phosphorescent aggregate and a blue-emitting phosphorescent dopant in a white OLED. In some embodiments, the structure comprises a thin blue emissive layer adjacent to the electron blocking layer (EBL) that comprises a balanced charge transporting host system, and a blue phosphorescent emitting dopant. On the end of the thin blue emissive layer, opposite to the EBL, there is a thin orange emissive layer comprising an aggregate emitter or an aggregate emitter doped in a host or host system. In some embodiments, the orange aggregate has weak absorption of wavelengths from 450-550 nm and is efficient and stable in a device setting. An example of an efficient and stable orange aggregate emitter is Pd308-p (FIG. 5) which demonstrated a peak EQE of over 34% in its neat film devices, a peak emission wavelength of around 580 nm, and a long device operational lifetime with LT95 of over 15,000 hours at 1000 nits. This for example can be combined with the blue phosphorescent emitter PtON5-Pdb-tbu (FIG. 5) to create a reasonably color stable WOLED that simultaneously demonstrates high EQEs of around 15-20%, balanced emission, and good lifetime. The device color can be tuned using different emissive materials, different transporting materials, and/or changing the thicknesses of the transporting layers.

In some embodiments, an organic light emitting device (OLED) 200 comprises a substrate 202, a first electrode 204 over the substrate 202, an emissive layer (EML) 208 over the first electrode 204 comprising a first thin emissive sub-layer 208A and a second thin emissive sub-layer 208B over the first, and a second electrode 212 over the emissive layer 208. In some embodiments, the OLED 200 further comprises a hole transport layer (HTL) 206 between the first electrode 204 and the EML 208. In some embodiments, the OLED 200 further comprises an electron transport layer (ETL) 210 between the EML 208 and the second electrode 212.

In some embodiments, the first thin emissive sub-layer 208A comprises a doped phosphorescent emissive sub-layer. In some embodiments, the second thin emissive sub-layer 208B comprises an aggregate emissive sub-layer. In some embodiments, the first thin emissive sub-layer 208A is less than 10 nm thick. In some embodiments, the second thin emissive sub-layer 208B is less than 10 nm thick. In some embodiments, the emissive sub-layer 208B is greater than 10 nm thick. In some embodiments, the emissive sub-layer 208B is less than 40 nm thick.

In some embodiments, the OLED 200 has an efficiency of at least 15%. In some embodiments, the OLED 200 emits white light. In some embodiments, a color output of the OLED 200 is tunable based on thicknesses of the first emissive sub-layer 208A and the second emissive sub-layer 208B. In some embodiments, a color temperature of the device is tunable based on thicknesses of the first emissive sub-layer 208A and the second emissive sub-layer 208B.

In some embodiments, the first thin emissive sub-layer 208A comprises a blue emissive sub-layer. In some embodiments, the second thin emissive sub-layer 208B comprises an orange emissive sub-layer.

In some embodiments, the first thin emissive sub-layer 208A is positioned between the second thin emissive sub-layer 208B and an electron blocking layer (EBL) 206A and/or HTL 206. In some embodiments, the EBL 206A and/or HTL 206 is positioned between the first thin emissive sub-layer 208A and the first electrode 204, wherein the first electrode 204 comprises an anode.

In some embodiments, the second thin emissive sub-layer 208B comprises a first orange emitter material and a host material. In some embodiments, the orange emitter material is at least 20% by weight of the second thin emissive sub-layer 208B. In some embodiments, the orange emitter material is at least 20% by volume of the second thin emissive sub-layer 208B.

In some embodiments, the first thin emissive sub-layer 208A comprises PtON5-pdb-tbu: 60 wt. % SiBCz: 30 wt. % SiTrzCz2. In some embodiments, the second thin emissive sub-layer 208B comprises Pd308-p. In some embodiments, the first electrode 204 comprises an anode comprising ITO. In some embodiments, the second electrode 212 comprises a metal cathode.

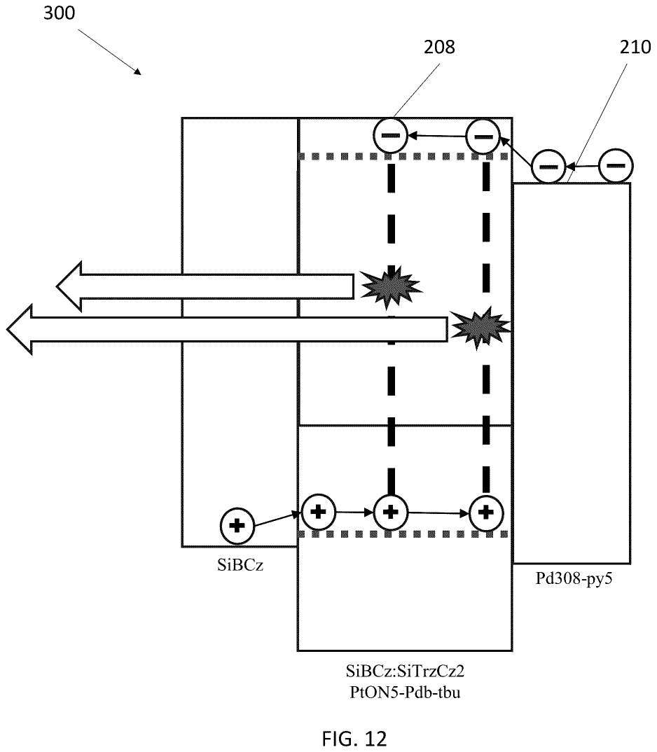

In some embodiments, the OLED 200 has an emissive layer (EML) 208 in direct contact with a thin electron transport layer 210 (ETL) (FIG. 12). In some embodiments, the electron transport layer has a thickness of less than 10 nm. In some embodiments, the electron transport layer comprises an aggregate material. In some embodiments, the electron transport layer consists of the aggregate material.

In some embodiments, the electron transport layer has a thickness of less than 9 nm, less than 8 nm, less than 7 nm, less than 6 nm, less than 5 nm, less than 4 nm, less than 3 nm, less than 2 nm, or less than 1 nm. In some embodiments, the electron transport layer has a thickness between 0.5 nm and 10 nm. In some embodiments, the electron transport layer has a thickness between 0.5 nm and 5 nm. In some embodiments, the electron transport layer has a thickness between 1 nm and 5 nm. In some embodiments, the electron transport layer has a thickness between 1 nm and 5 nm. In some embodiments, the electron transport layer has a thickness between 1 nm and 3 nm. In some embodiments, the electron transport layer has a thickness between 2 nm and 5 nm. In some embodiments, the electron transport layer further comprises a host material.

In some embodiments, the aggregate material has a first absorption coefficient over, wherein the first absorption coefficient is less than 0.1 cm⁻¹, and wherein the organic light-emitting device emits light of a first wavelength, wherein the first wavelength is from 450-550 nm. In some embodiments, the first absorption coefficient is less than 0.09 cm⁻¹, less than 0.08 cm⁻¹, less than 0.07 cm⁻¹, less than 0.06 cm⁻¹, less than 0.05 cm⁻¹, less than 0.04 cm⁻¹, less than 0.03 cm⁻¹, less than 0.02 cm⁻¹, less than 0.01 cm⁻¹, or less than 0.005 cm⁻¹.

In some embodiments, the aggregate material has a band gap larger than 1.0 eV. In some embodiments, the aggregate material has a band gap larger than 1.5 eV. In some embodiments, the aggregate material has a band gap larger than 2.0 eV. In some embodiments, the aggregate material has a band gap larger than 2.5 eV. In some embodiments, the aggregate material has a band gap larger than 3.0 eV. In some embodiments, the aggregate material has a band gap larger than 3.5 eV. In some embodiments, the aggregate material has a band gap larger than 4.0 eV.

In some embodiments, the aggregate material comprises a metal complex. In some embodiments, the aggregate material comprises a Platinum (Pt) or Palladium (Pd) metal complex. In some embodiments, the aggregate material is a phosphorescent excimer. In some embodiments, the aggregate material is a square planar metal complex.

In some embodiments, the organic emissive layer has a thickness less than 40 nm. In some embodiments, the organic emissive layer has a thickness less than 35 nm. In some embodiments, the organic emissive layer has a thickness less than 30 nm. In some embodiments, the organic emissive layer has a thickness less than 25 nm. In some embodiments, the organic emissive layer has a thickness less than 20 nm.

In some embodiments, the organic emissive layer has a thickness greater than 5 nm. In some embodiments, the organic emissive layer has a thickness greater than 10 nm. In some embodiments, the organic emissive layer has a thickness greater than 15 nm. In some embodiments, the organic emissive layer has a thickness greater than 20 nm. In some embodiments, the organic emissive layer has a thickness greater than 25 nm.

In some embodiments, the organic emissive layer has a thickness between 5 and 50 nm. In some embodiments, the organic emissive layer has a thickness between 10 and 50 nm. In some embodiments, the organic emissive layer has a thickness between 15 and 50 nm. In some embodiments, the organic emissive layer has a thickness between 20 and 50 nm. In some embodiments, the organic emissive layer has a thickness between 25 and 50 nm. In some embodiments, the organic emissive layer has a thickness between 5 and 25 nm. In some embodiments, the organic emissive layer has a thickness between 10 and 25 nm. In some embodiments, the organic emissive layer has a thickness between 15 and 25 nm. In some embodiments, the organic emissive layer has a thickness between 20 and 25 nm.

In some embodiments, the organic light emitting device emits blue light. In some embodiments, the organic light-emitting device emits light of a first wavelength, wherein the first wavelength is between 450 nm and 550 nm.

In some embodiments, the organic emissive layer comprises a first host material and a second host material; wherein the first host material is a p-type host; and wherein the second host material is an n-type host. In some embodiments, the organic emissive layer comprises a host represented by one or both of the following structures:

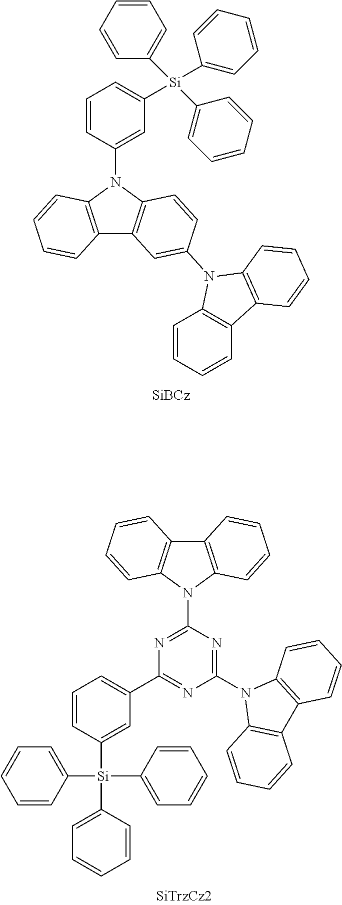 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

In some embodiments, the organic emissive layer comprises a phosphorescent emitter represented by the following structure:

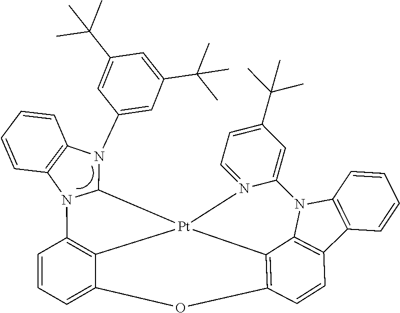

Examples of phosphorescent excimers with yellow and amber emission (e.g., having a wavelength in a range of or covering the range of about 480 nm to about 700 nm) suitable for emissive sublayer 208B or for electron transport layer 210 include complexes represented by General Formula.

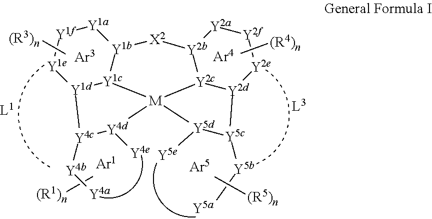

In General Formula I: M represents Pt(II) or Pd(II); R¹, R³, R⁴, and R⁵ each independently represents hydrogen, halogen, hydroxyl, nitro, cyanide, thiol, or optionally substituted C₁-C₄ alkyl, alkoxy, amino, or aryl; each n is independently an integer, valency permitting; Y^{1a}, Y^{1b}, Y^{1c}, Y^{1d}, Y^{1e}, Y^{1f}, Y^{2a}, Y^{2b}, Y^{2c}, Y^{2d}, Y^{2e}, Y^{2f}, Y^{4a}, Y^{4b}, Y^{4c}, Y^{4d}, Y^{4e}, Y^{5a}, Y^{5b}, Y^{5c}, Y^{5d}, and Y^{5e} each independently represents C, N, Si, O, S; X² represents NR, PR, CRR′, SiRR′, CRR′, SiRR′, O, S, S═O, O═S═O, Se, Se═O, or O═Se═O, where R and R′ each independently represents hydrogen, halogen, hydroxyl, nitro, cyanide, thiol, or optionally substituted C₁-C₄ alkyl, alkoxy, amino, aryl, or heteroaryl; each of L¹ and L³ is independently present or absent, and if present, represents a substituted or unsubstituted linking atom or group, where a substituted linking atom is bonded to an alkyl, alkoxy, alkenyl, alkynyl, hydroxy, amine, amide, thiol, aryl, heteroaryl, cycloalkyl, or heterocyclyl moiety; Ar³ and Ar⁴ each independently represents a 6-membered aryl group; and Ar¹ and Ar⁵ each independently represents a 5- to 10-membered aryl, heteroaryl, fused aryl, or fused heteroaryl.

Examples of complexes represented by General Formula I are shown below:

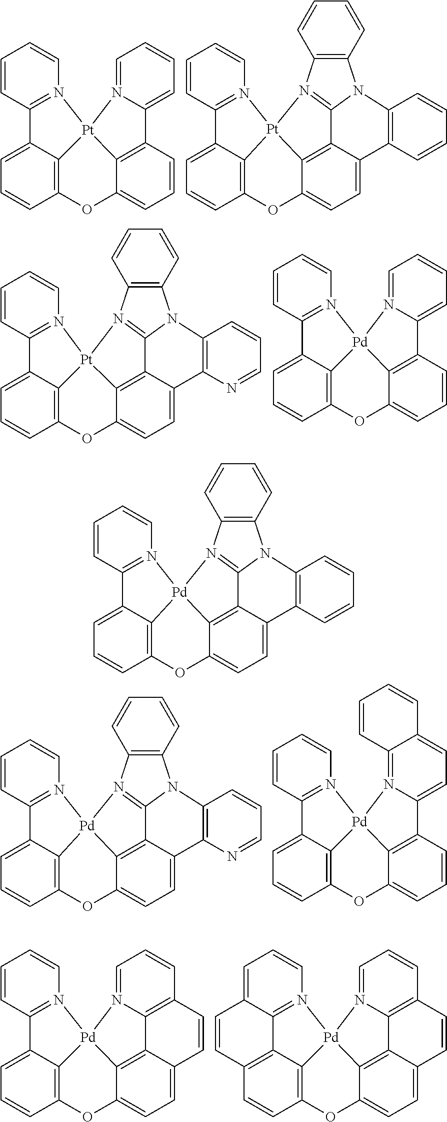

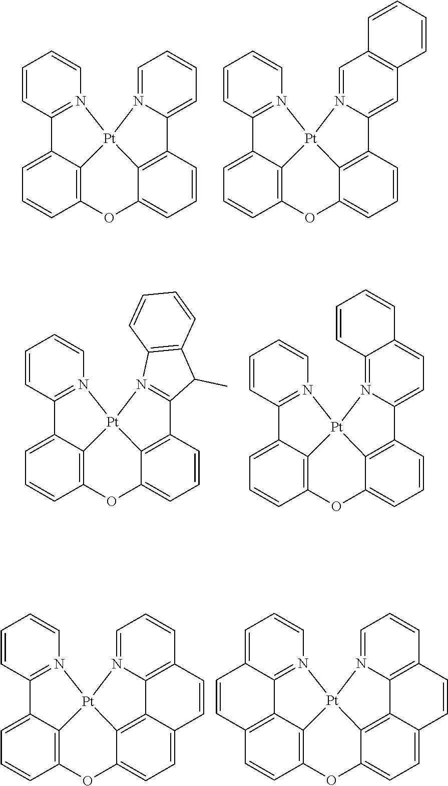

In some embodiments, the emitters suitable for emissive layer 208B or electron transport layer 210 include square planar tetradentate platinum and palladium complexes represented by General Formulas II-IX.

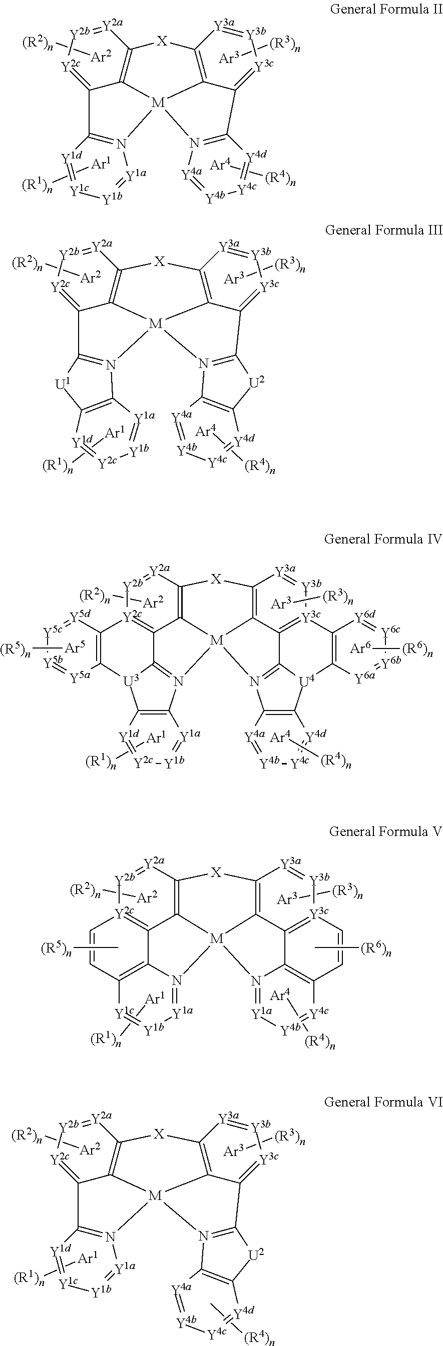

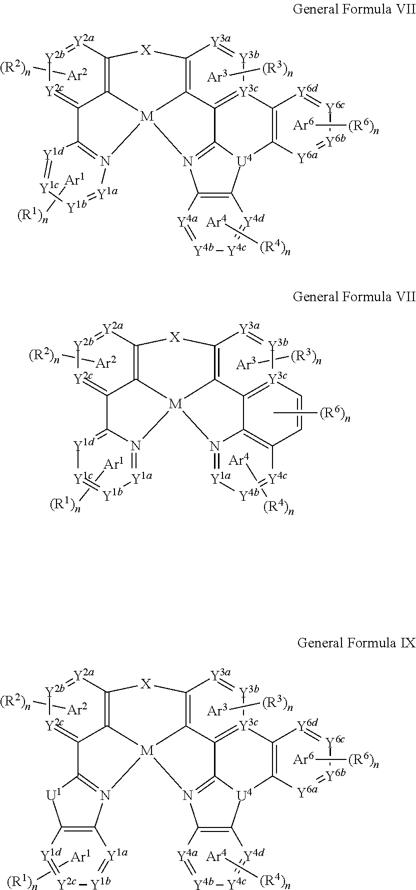

In General Formulas II-IX: M represents Pt(II) or Pd(II); R¹, R², R³, R⁴, R⁵, and R⁶ each independently represents hydrogen, halogen, hydroxyl, nitro, nitrile, thiol, or optionally substituted C₁-C₄ alkyl, alkoxy, amino, or aryl; each n is independently an integer, valency permitting; Y^{1a}, Y^{1b}, Y^{1c}, Y^{1d}, Y^{1a}, Y^{1b}, Y^{1c}, Y^{1d}, Y^{1e}, Y^{1f}, Y^{2a}, Y^{2b}, Y^{2c}, Y^{2d}, Y^{2e}, Y^{2f}, Y^{4a}, Y^{4b}, Y^{4c}, Y^{4d}, Y^{4e}, Y^{5a}, Y^{5b}, Y^{5c}, Y^{5d}, and Y^{5e} each independently represents C, N, or Si; U¹ and U² each independently represents NR, O or S, wherein R represents hydrogen, halogen, hydroxyl, nitro, nitrile, thiol, or optionally substituted C₁-C₄ alkyl, alkoxy, amino, or aryl; U³ and U⁴ each independently represents N or P; and X represents O, S, NR, CRR′, SiRR′, PR, BR, S═O, O═S═O, Se, Se═O, or O═Se═O, where R and R′ each independently represents hydrogen, halogen, hydroxyl, nitro, nitrile, thiol, or optionally substituted C₁-C₄ alkyl, alkoxy, amino, aryl, or heteroaryl.

Examples of complexes of Formula II-IX are shown below:

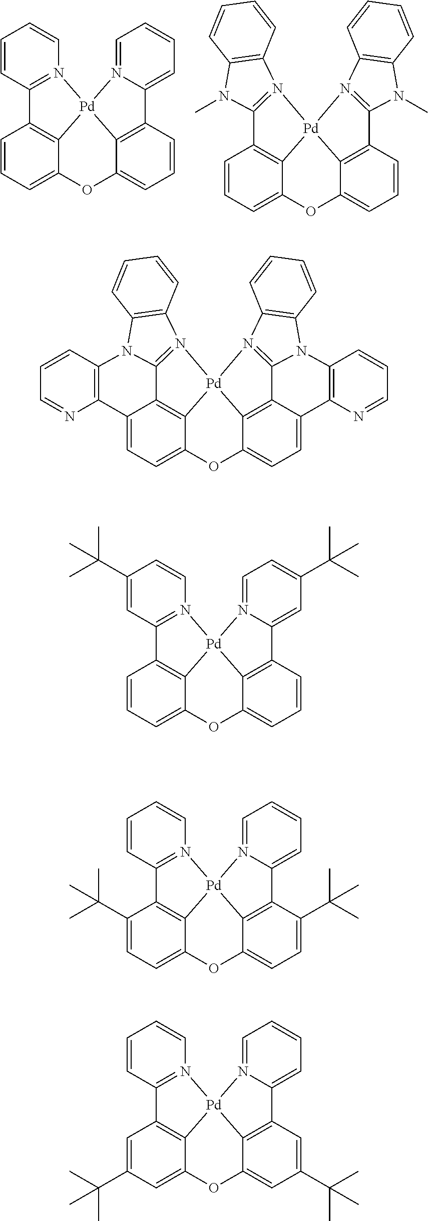

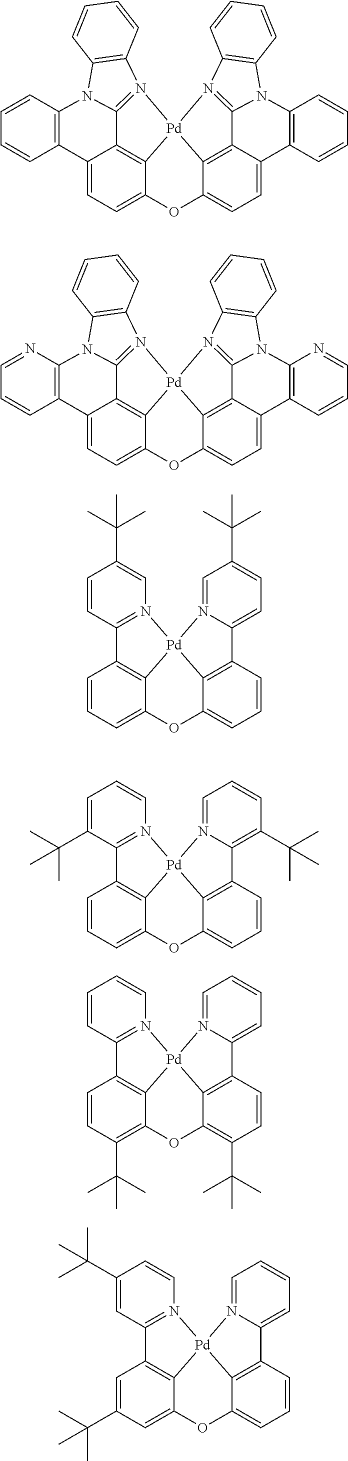

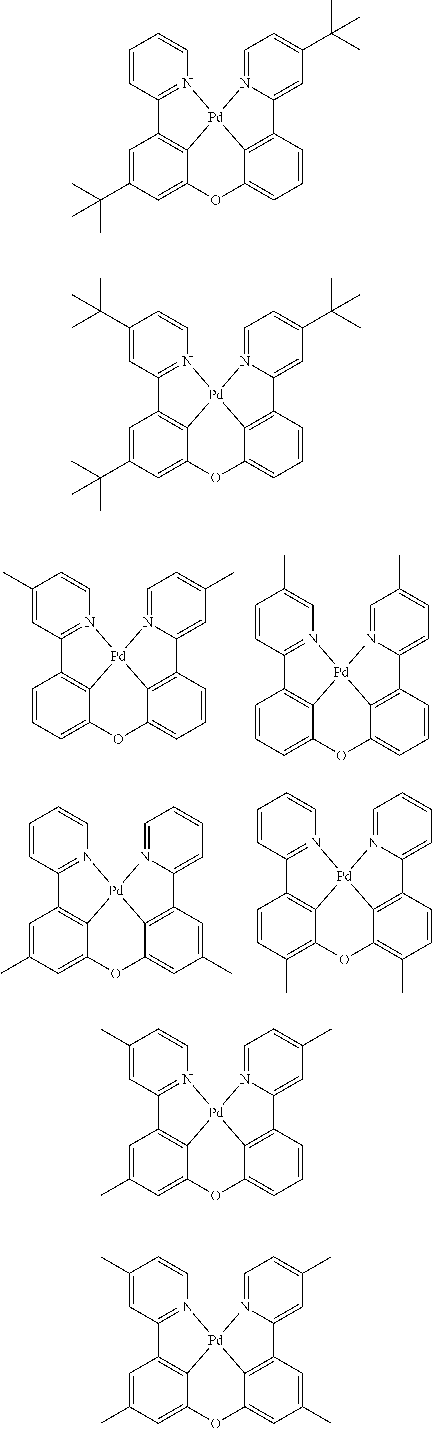

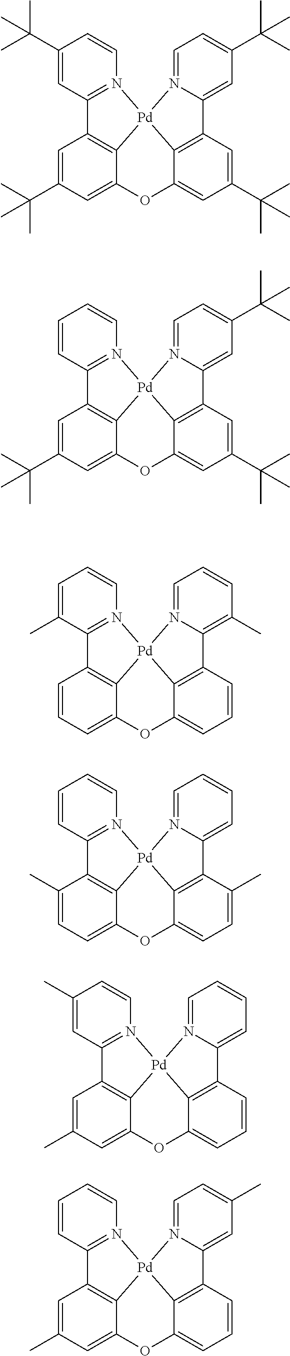

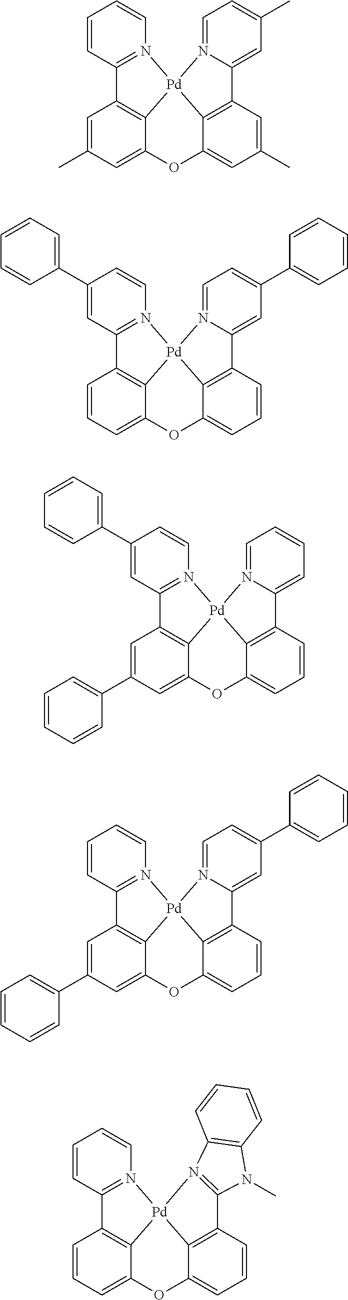

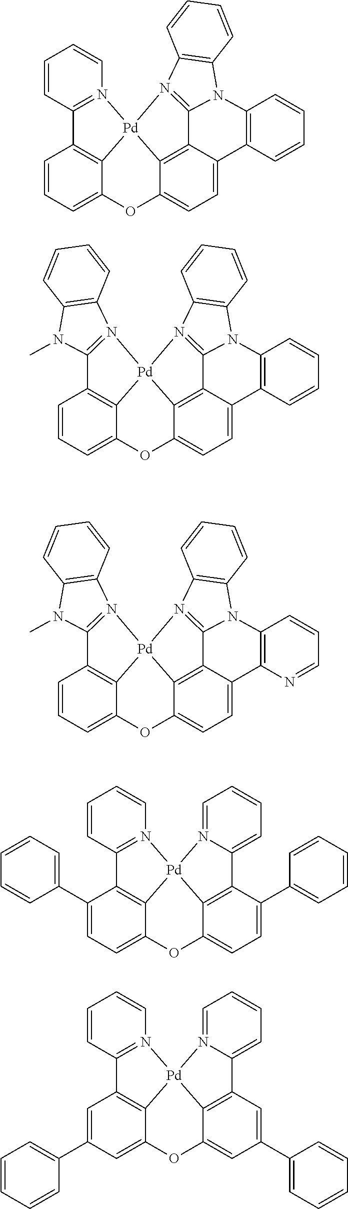

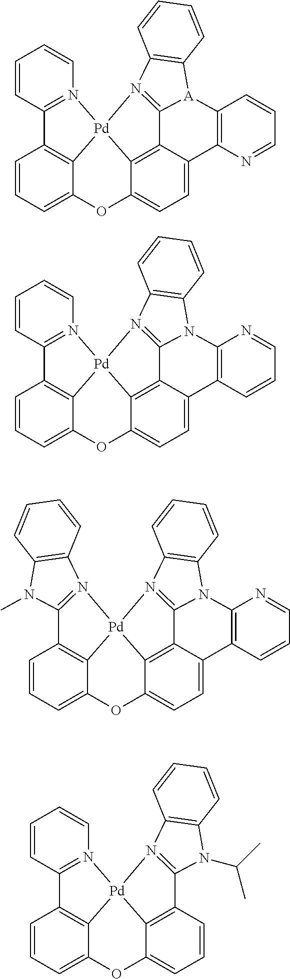

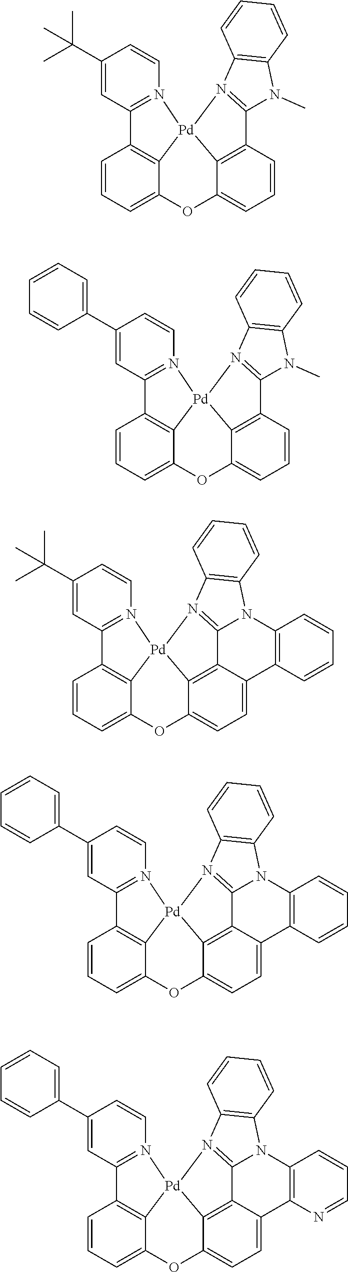

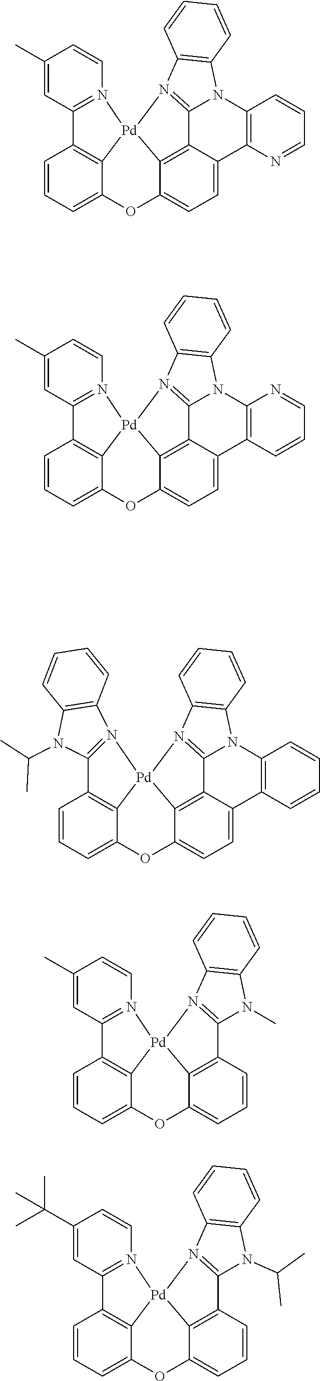

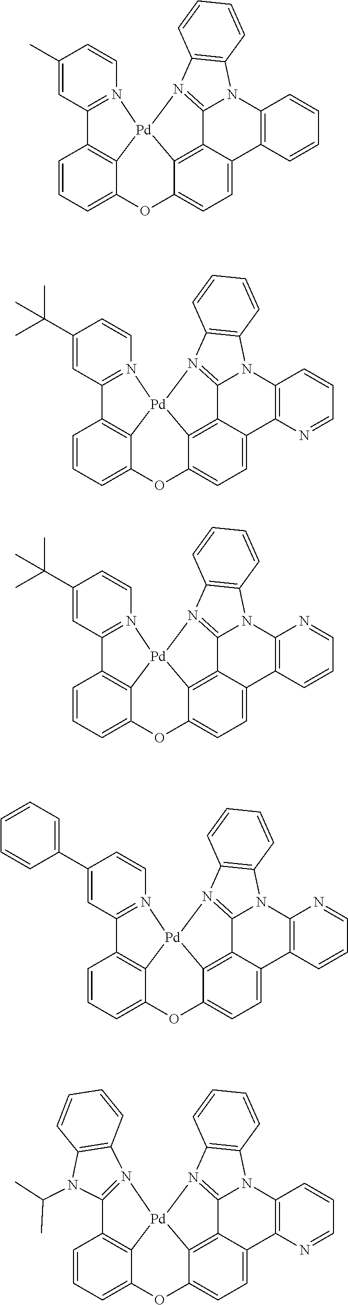

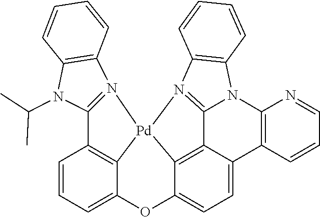

### EXPERIMENTAL EXAMPLES

The invention is now described with reference to the following Examples. These Examples are provided for the purpose of illustration only and the invention should in no way be construed as being limited to these Examples, but rather should be construed to encompass any and all variations which become evident as a result of the teaching provided herein.

Without further description, it is believed that one of ordinary skill in the art can, using the preceding description and the following illustrative examples, make and utilize the present invention and practice the claimed methods. The following working examples therefore, specifically point out exemplary embodiments of the present invention, and are not to be construed as limiting in any way the remainder of the disclosure.

### Example 1: Efficient and Stable all Phosphorescent White Organic Light Emitting Diodes with Excellent Color Stability

FIGS. 5A-5D show plots of Current density-voltage characteristics (FIG. 5A), EQE versus luminance (FIG. 5B), EL spectra at current densities of 1 mA cm⁻² (FIG. 5C), and relative luminance versus operational time at a constant current density (FIG. 5D) of 5 mA cm⁻² for devices 1-2 where the devices comprised of 60 nm ITO/10 nm HATCN/60 nm NPD/5 nm SiBCz/EML/5 nm Si2TrzPh/30 nm 50 wt. % Si2TrzPh: 50 wt. % Liq/2 nm Liq/100 nm Al, where EML is 10 wt. % PtON5-pdb-tbu: 60 wt. % SiBCz: 30 wt. % SiTrzCz2 (5 nm)/Pd308-p 5 nm for device 1 and 10 wt. % PtON5-pdb-tbu: 60 wt. % SiBCz: 30 wt. % SiTrzCz2 (10 nm)/Pd308-p 5 nm for device 2.

The EL spectra for the two devices are significantly different where device 1 shows near balanced emission between blue and orange while device 2 shows almost entirely blue emission. This supports the claim that the blue layer must be thin.

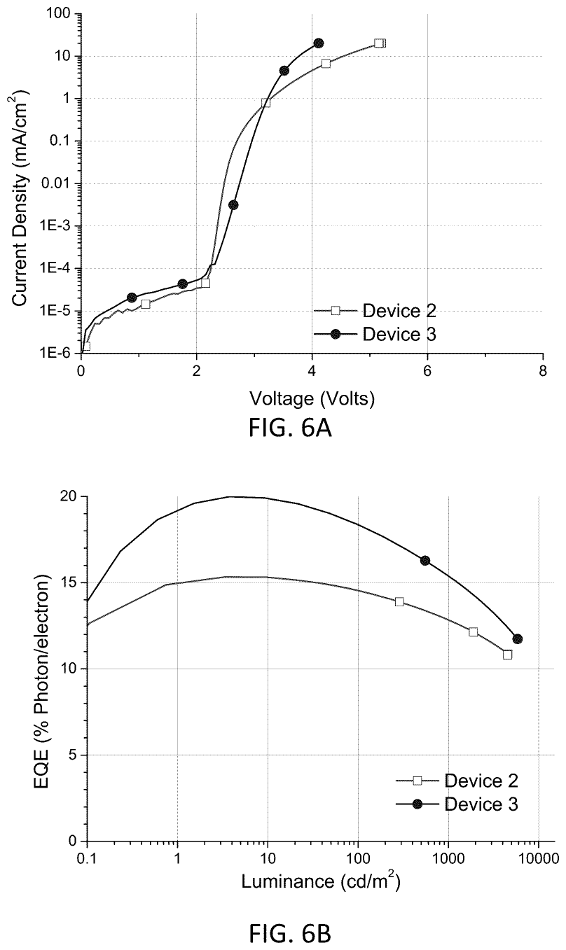

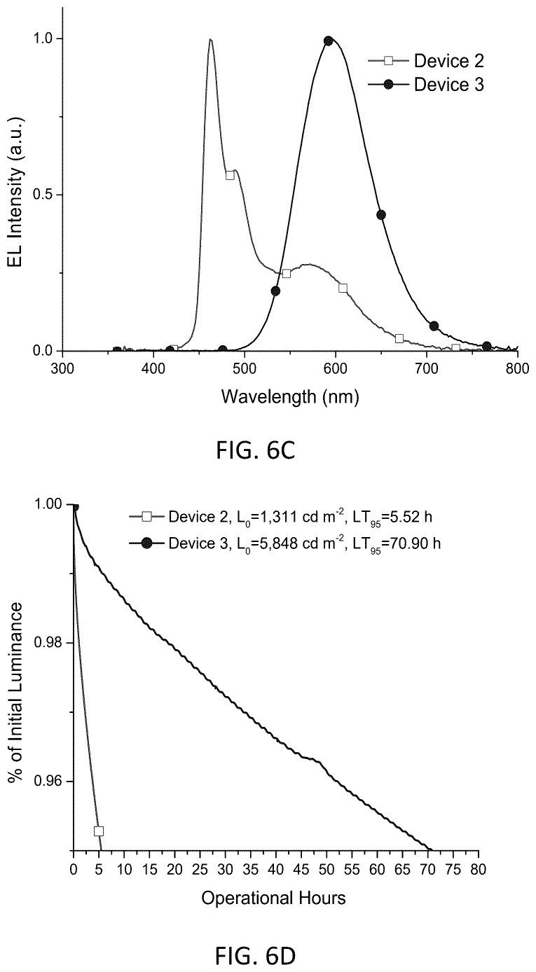

FIGS. 6A-6D show plots of Current density-voltage characteristics (FIG. 6A), EQE versus luminance (FIG. 6B), EL spectra at current densities of 1 mA cm⁻² (FIG. 6C), and relative luminance versus operational time at a constant current density (FIG. 6D) of 5 mA cm⁻² for device 2 and 20 mA cm⁻² for device 3.

Device 2 had a structure of 60 nm ITO/10 nm HATCN/60 nm NPD/5 nm SiBCz/10 wt. % PtON5-pdb-tbu: 60 wt. % SiBCz: 30 wt. % SiTrzCz2 (10 nm)/Pd308-P (5 nm)/5 nm Si2TrzPh/30 nm 50 wt. % Si2TrzPh: 50 wt. % Liq/2 nm Liq/100 nm Al.

Device 3 had a structure of 60 nm ITO/10 nm HATCN/40 nm NPD/5 nm SiBCz/Pd308-Py5 (5 nm)/10 wt. % PtON5-dtb: 60 wt. % SiBCz: 30 wt. % SiTrzCz2 (10 nm)/5 nm Si2TrzPh/30 nm Bpytp/2 nm Liq/100 nm Al.

The EL spectra for the two devices are significantly different where device 2 shows significant blue emission with a minor orange contribution while device 3 shows no blue contribution at all. This supports the claim that the blue layer must be placed near the HBL in the given structure.

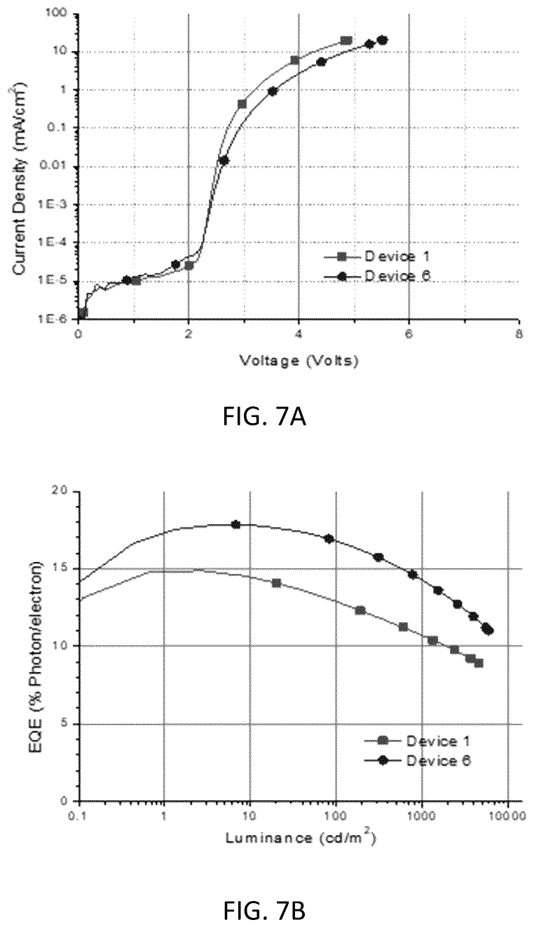

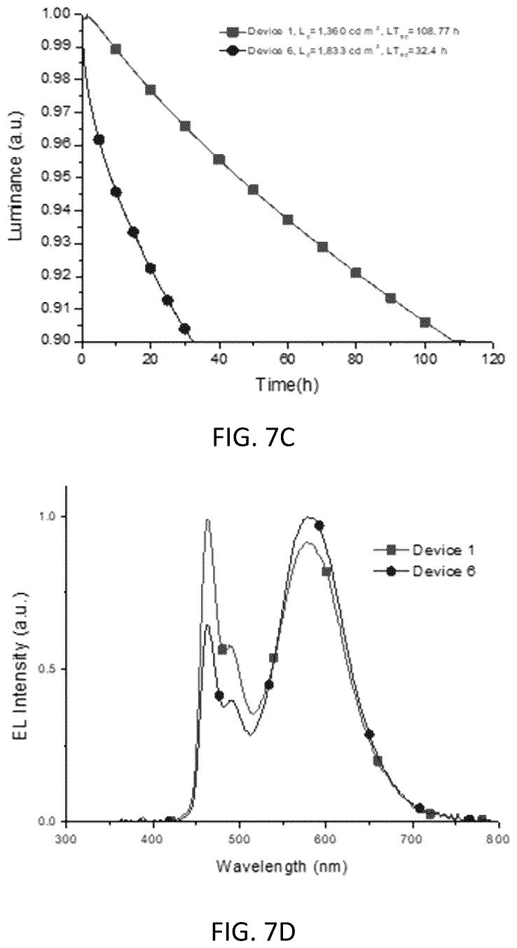

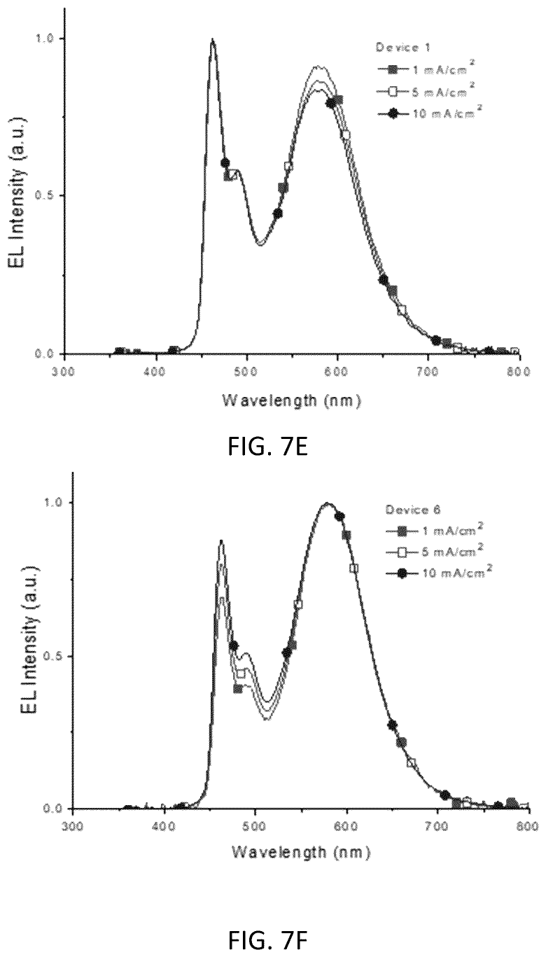

FIGS. 7A-7F show plots of Current density-voltage characteristics (FIG. 7A), EQE versus luminance (FIG. 7B), relative luminance versus operational time at a constant current density of 5 mA cm⁻² (FIG. 7C), EL spectra at current densities of 1 mA cm⁻² (FIG. 7D), EL spectra of device 1 at current densities of 1, 5 and 10 mA cm⁻² (FIG. 7E), and EL spectra of device 6 at current densities of 1, 5, and 10 mA cm⁻² for devices 1 and 6 (FIG. 7F) where the devices comprised of a structure of 60 nm ITO/10 nm HATCN/60 nm NPD/5 nm SiBCz/EML/5 nm Si2TrzPh/30 nm 50 wt. % Si2TrzPh: 50 wt. % Liq/2 nm Liq/100 nm Al, where EML is 10 wt. % PtON5-pdb-tbu: 60 wt. % SiBCz: 30 wt. % SiTrzCz2 (5 nm)/Pd308-p 5 nm for device 1 and 10 wt. % PtON5-pdb-tbu: 60 wt. % SiBCz: 30 wt. % SiTrzCz2 (10 nm)/50 wt. % Pd308-p: 33 wt. % SiBCz: 17 wt. % SiTrzCz2 5 nm/Pd308-p 5 nm for device 6.

The two devices both show reasonable color stability with simultaneous high EQEs of around 15-20%, balanced emission, and good lifetime. This supports the claim that doped aggregate emissive layers also work.

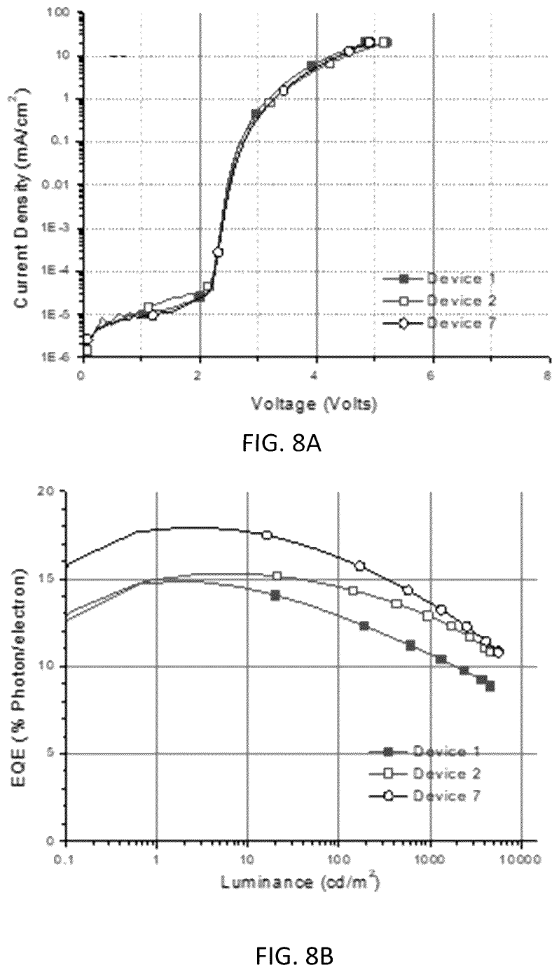

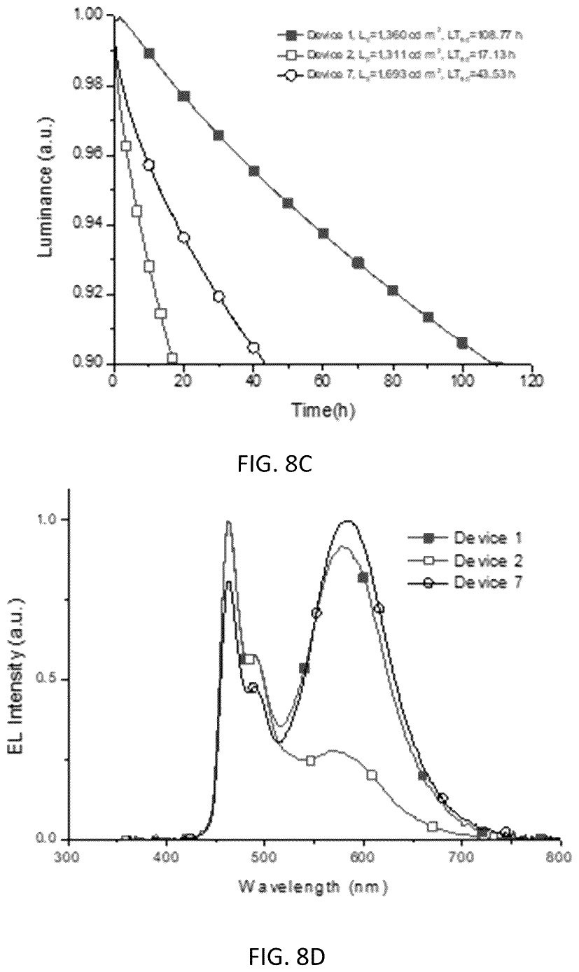

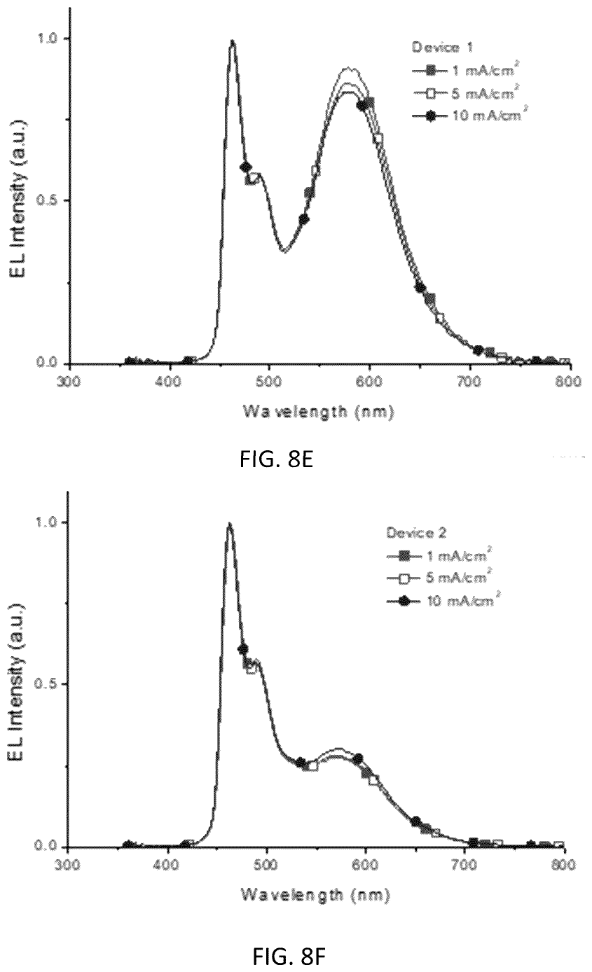

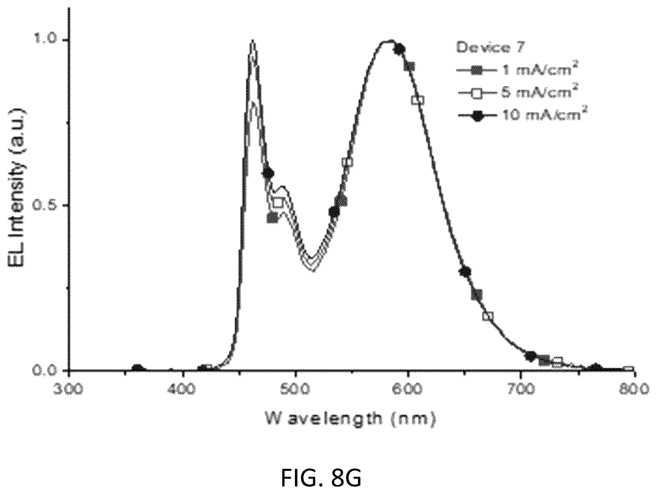

FIGS. 8A-8G show plots of Current density-voltage characteristics (FIG. 8A), EQE versus luminance (FIG. 8B), relative luminance versus operational time at a constant current density of 5 mA cm⁻² (FIG. 8C), EL spectra at current densities of 1 mA cm⁻² (FIG. 8D), EL spectra of device 1 at current densities of 1, 5 and 10 mA cm⁻² (FIG. 8E), EL spectra of device 2 at current densities of 1, 5 and 10 mA cm⁻² (FIG. 8F), and EL spectra of device 7 at current densities of 1, 5 and 10 mA cm⁻² for devices 1, 2 and 7 (FIG. 8G) where the devices comprised of 60 nm ITO/10 nm HATCN/60 nm NPD/5 nm SiBCz/EML/5 nm Si2TrzPh/30 nm 50 wt. % Si2TrzPh: 50 wt. % Liq/2 nm Liq/100 nm Al, where EML is 10 wt. % PtON5-pdb-tbu: 60 wt. % SiBCz: 30 wt. % SiTrzCz2 (5 nm)/Pd308-p 5 nm for device 1, 10 wt. % PtON5-pdb-tbu: 60 wt. % SiBCz: 30 wt. % SiTrzCz2 (10 nm)/Pd308-p 5 nm for device 2, and 10 wt. % PtON5-pdb-tbu: 60 wt. % SiBCz: 30 wt. % SiTrzCz2 (10 nm)/Pd308-p 8 nm for device 7.

Device 1 with equal thicknesses of the orange and blue EMLs had near balanced color. Device 2 with a relatively thicker blue emissive layer had significantly more blue color than device 1. Device 7 with a relatively thicker orange emissive layer had significantly more orange color than device 1. The presented data supports the claim that the color of the white devices can be tuned with varied blue or orange EML thicknesses.

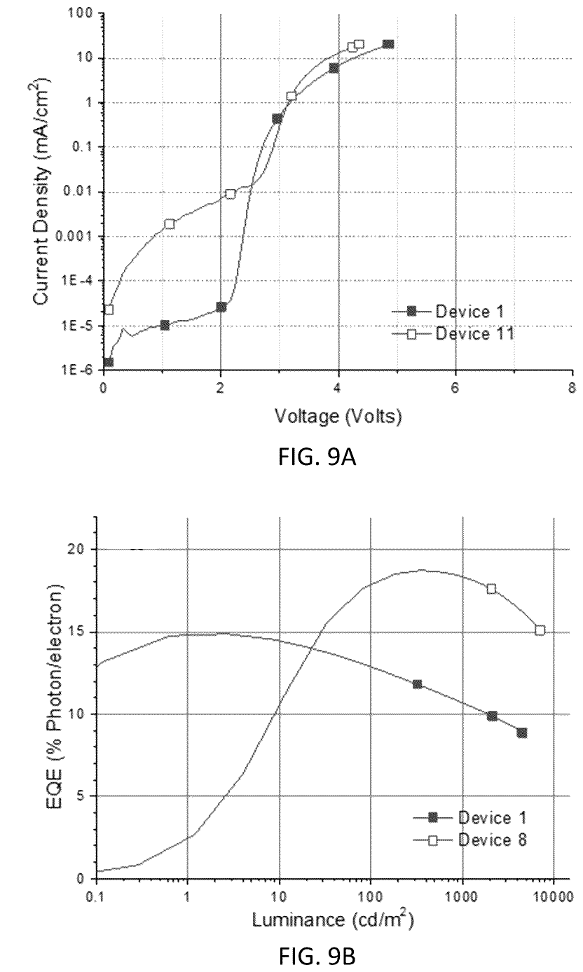

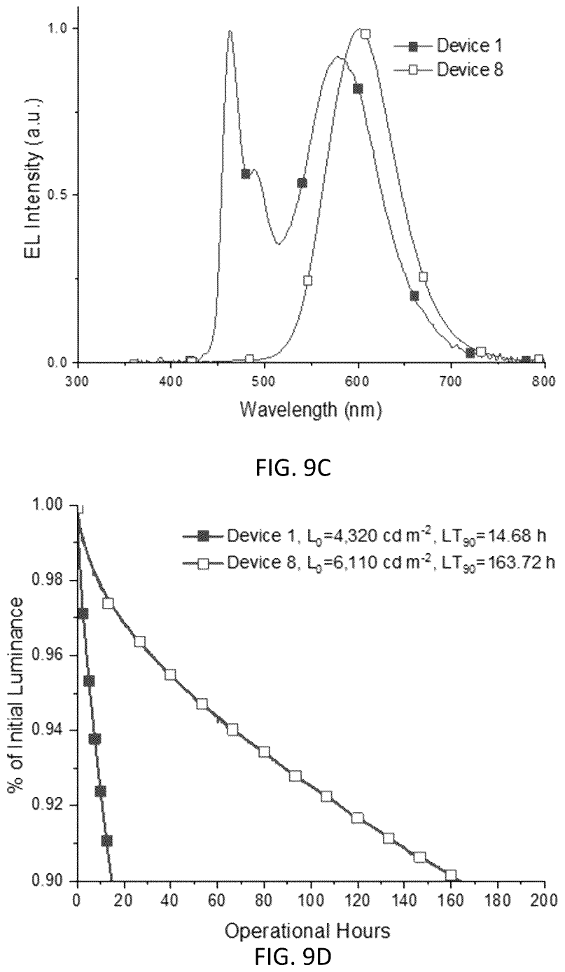

FIGS. 9A-9D show plots of Current density-voltage characteristics (FIG. 9A), EQE versus luminance (FIG. 9B), EL spectra at current densities of 1 mA cm⁻² (FIG. 9C), and relative luminance versus operational time at a constant current density (FIG. 9D) of 5 mA cm⁻² for device 1 and 20 mA cm⁻² for device 8.

Device 1 had a structure of 60 nm ITO/10 nm HATCN/60 nm NPD/5 nm SiBCz/10 wt. % PtON5-pdb-tbu: 60 wt. % SiBCz: 30 wt. % SiTrzCz2 (5 nm)/Pd308-p 5 nm/5 nm Si2TrzPh/30 nm 50 wt. % Si2TrzPh: 50 wt. % Liq/2 nm Liq/100 nm Al.

Device 8 had a structure of 100 nm ITO/10 nm HATCN/70 nm NPD/10 nm Trispcz/10 wt. % PtNON: 90 wt. % MCBP (5 nm)/Pd308-py5 5 nm/10 nm Balq/40 nm Bpytp/2 nm Liq/100 nm Al.

Of note here is the significant difference in EL spectra for the two devices. Device 1 had near balanced emission and device 8 had sole orange emission. This supports the claim that there should be a blue dopant in a balance charge transporting host system.

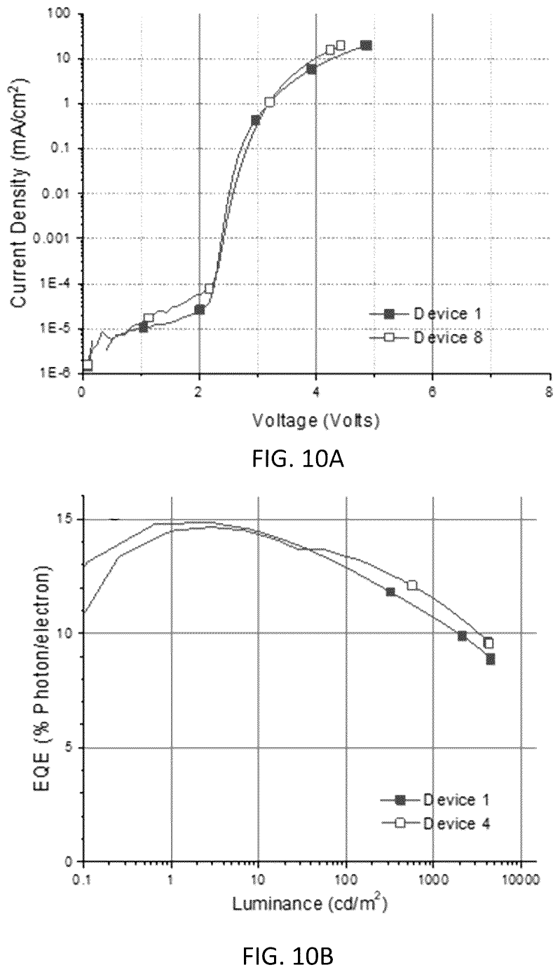

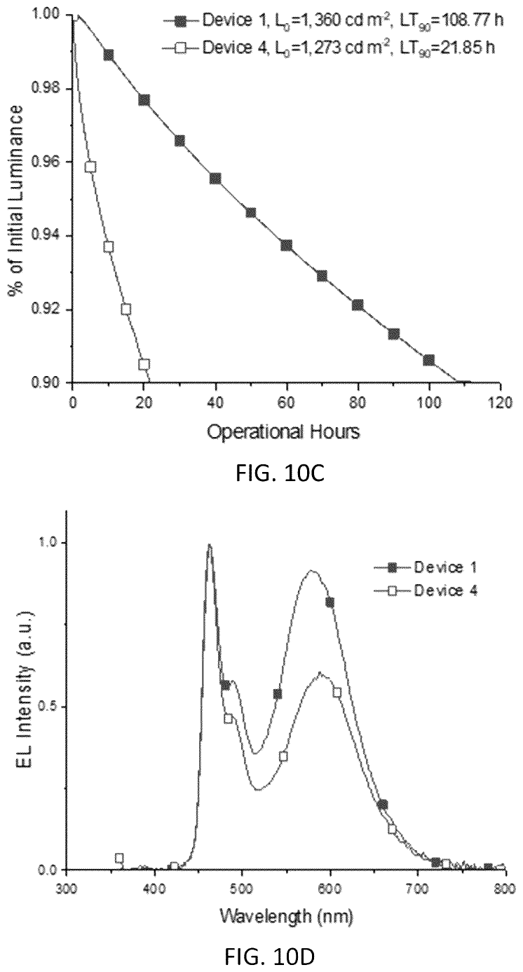

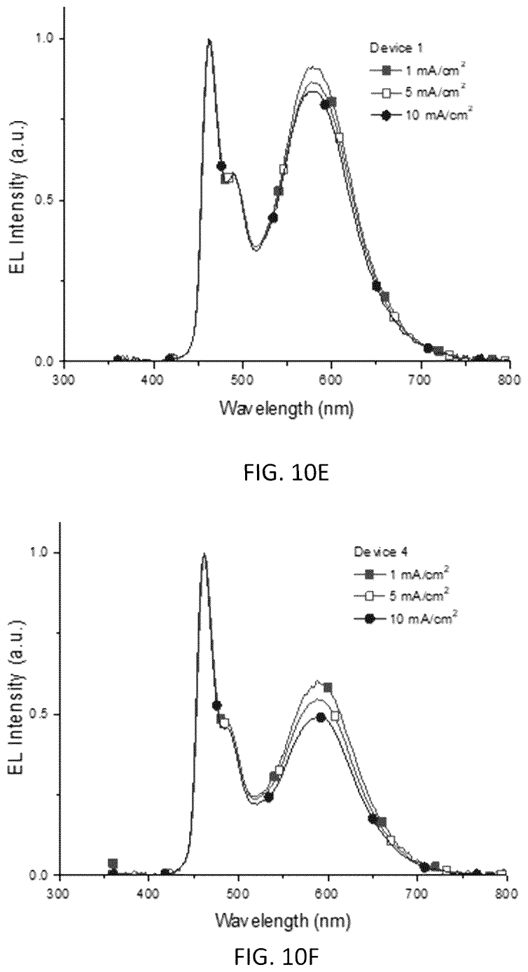

FIGS. 10A-10F show plots of Current density-voltage characteristics (FIG. 10A), EQE versus luminance (FIG. 10B), EL spectra at current densities of 1 mA cm⁻² (FIG. 10C), relative luminance versus operational time at a constant current density of 5 mA cm⁻² (FIG. 10D), EL spectra of device 1 at current densities of 1, 5 and 10 mA cm⁻² (FIG. 10E), and EL spectra of device 4 at current densities of 1, 5 and 10 mA cm⁻² (FIG. 10F).

Device 1 had a structure of 60 nm ITO/10 nm HATCN/60 nm NPD/5 nm SiBCz/10 wt. % PtON5-pdb-tbu: 60 wt. % SiBCz: 30 wt. % SiTrzCz2 (5 nm)/Pd308-P (5 nm)/5 nm Si2TrzPh/30 nm 50 wt. % Si2TrzPh: 50 wt. % Liq/2 nm Liq/100 nm Al.

Device 4 had a structure of 100 nm ITO/10 nm HATCN/75 nm NPD/5 nm SiBCz/10 wt. % PtON5-pdb-tbu: 60 wt. % SiBCz: 30 wt. % SiTrzCz2 (5 nm)/Pd308-P (5 nm)/10 nm Balq/50 nm Bpytp/2 nm Liq/100 nm Al.

Again, the EL spectra are to be of note here where device 1 shows balanced emission and device 4 shows a roughly 2:1 blue-to-orange emission ratio. Also, despite the change in color, EQE, color stability, and operational stability remains reasonably high. This supports the claim that the color of the white device can be tuned through thickness and/or material changes to the transporting layers.

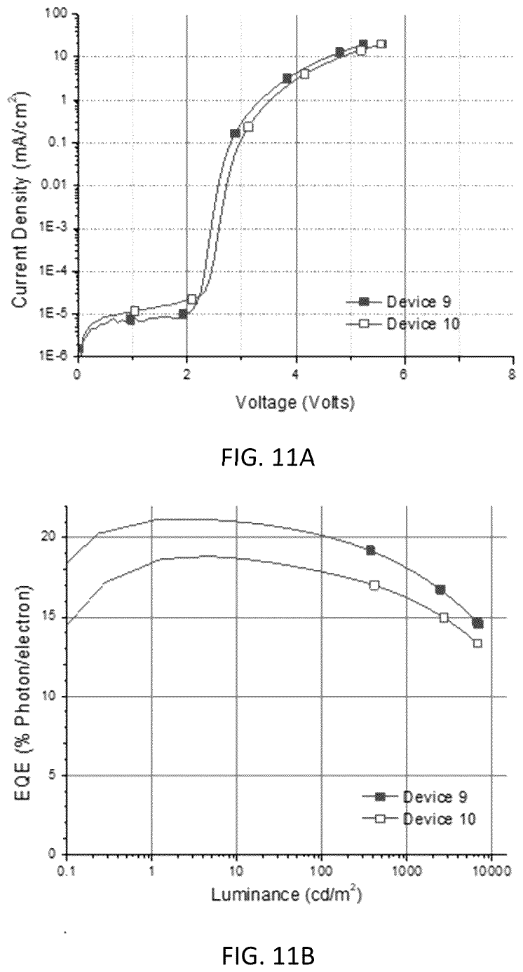

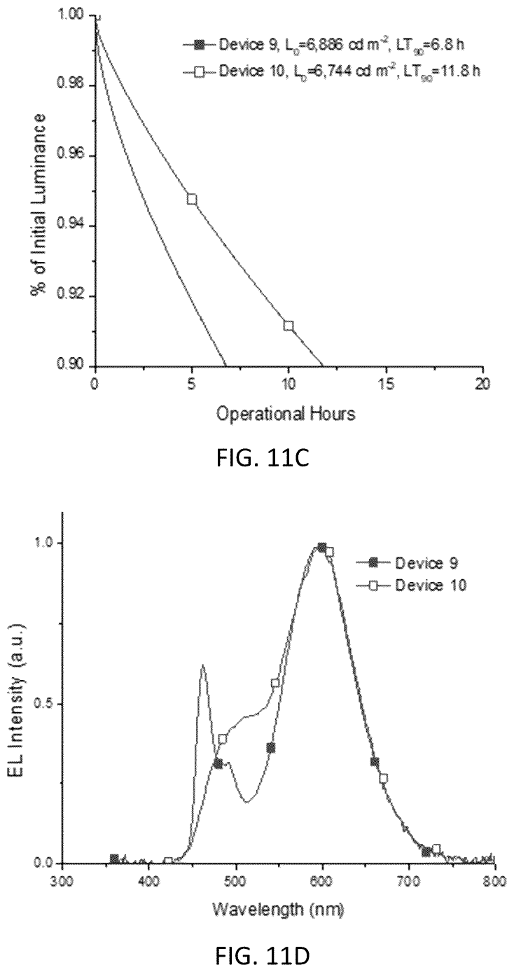

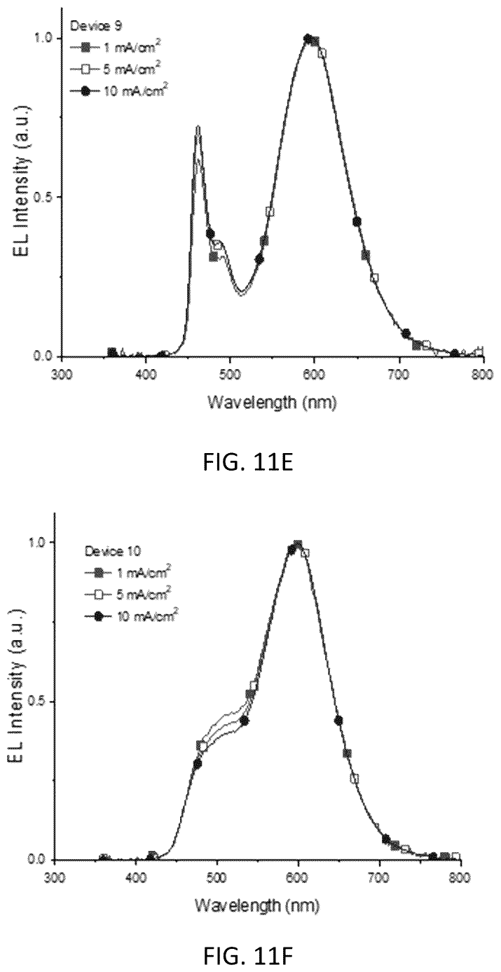

FIGS. 11A-11F show plots of Current density-voltage characteristics (FIG. 11A), EQE versus luminance (FIG. 11B), EL spectra at current densities of 1 mA cm⁻² (FIG. 11C), relative luminance versus operational time at a constant current density of 5 mA cm⁻² (FIG. 11D), EL spectra of device 9 at current densities of 1, 5 and 10 mA cm⁻² (FIG. 11E), and EL spectra of device 10 at current densities of 1, 5 and 10 mA cm⁻² (FIG. 11F).

Device 9 had a structure of 100 nm ITO/10 nm HATCN/75 nm NPD/5 nm SiBCz/10 wt. % PtON5-pdb-tbu: 60 wt. % SiBCz: 30 wt. % SiTrzCz2 (5 nm)/Pd308-P (10 nm)/10 nm Balq/10 nm Bpytp/50 nm 50 wt. % Bpytp: 50 wt. % Liq/2 nm Liq/100 nm Al.

Device 10 had a structure of 100 nm ITO/10 nm HATCN/75 nm NPD/5 nm SiBCz/10 wt. % PtNON: 60 wt. % SiBCz: 30 wt. % SiTrzCz2 (5 nm)/Pd308-Py5 (5 nm)/10 nm Balq/10 nm Bpytp/40 nm 50 wt. % Bpytp: 50 wt. % Liq/2 nm Liq/100 nm Al.

The two devices both demonstrate reasonably high EQE, color stability, and operational stability. Device 9 had a featured blue emission peak at 462 nm with a sideband at 490 nm while device 10 had a broad featureless blue emission peak at 508 nm. This supports the claim that the emissive layer materials can be changed to change the color quality of the white device.

### Example 2: Improved Operational Stability of Blue Phosphorescent Organic Light Emitting Diodes Through Judicious Placement of a Nanometer Scale Phosphorescent Aggregate Layer

Initiative of the invention: OLEDs have become a mainstay in the display industry due to their high device efficiencies, compatibility with flexible substrates, and potential for narrow emissions. The operational lifetime of blue phosphorescent OLED devices has prevented their widespread adoption in modern displays despite green and red devices already being heavily marketed. The problem with blue phosphorescent emitters stems from potentially long radiative decay lifetimes of such triplet excitons. Approaches to this problem are interdisciplinary where engineers, physicists, and chemists from industry and academia alike work together to solve this decades old problem. The development of stable and efficient blue phosphorescent emitters will contribute to the progress of more power efficient devices and potential adoption of OLEDs for solid state lighting.

The content of the invention: This invention is based on the usage of a phosphorescent aggregate and a blue-emitting phosphorescent dopant in a blue OLED. The structure will make use of a thick blue emissive layer adjacent to the electron blocking layer (EBL) that will consist of a balanced charge transporting host system, and a blue phosphorescent emitting dopant. At one end of the thick blue emissive layer, opposite to the EBL, there will be a one to two nanometer thick emissive layer consisting of an aggregate emitter. The aggregate will have weak absorption of wavelengths from 450-550 nm and will be efficient and stable in a device setting.

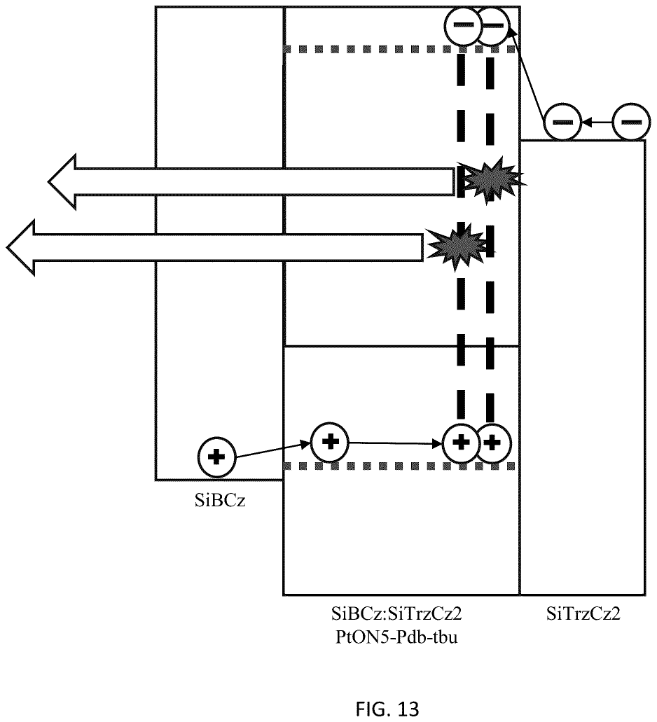

An example of an efficient and stable aggregate emitter is Pd308-py5 which demonstrated a peak EQE of over 37% in its neat film devices, a peak emission wavelength of around 580 nm and a long device operational lifetime with LT95 of over 48,000 hours at 1000 nits. A 1-2 nm layer of the aggregate can be as an injection layer with the blue phosphorescent emitter PtON5-Pdb-tbu (FIG. 12) to create an efficient OLED with improved operational stability with little change in device emission spectra. FIG. 13 shows a device lacking the 1-2 nm layer of the aggregate, which results in excitons forming only on one side of the layer. Conversely, in FIG. 12, the 1-2 nm layer of the aggregate results in excitons forming throughout the emissive layer which improves device stability and efficiency.

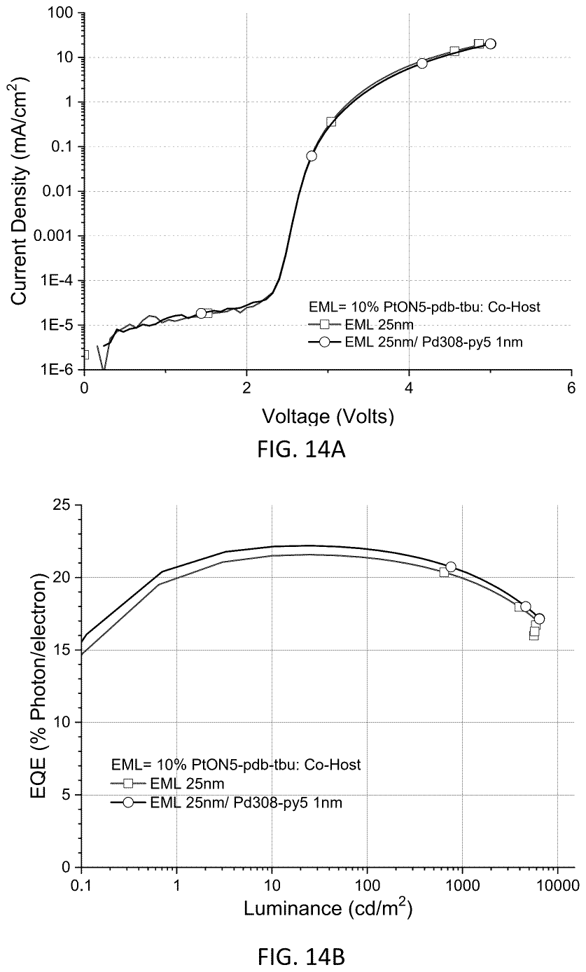

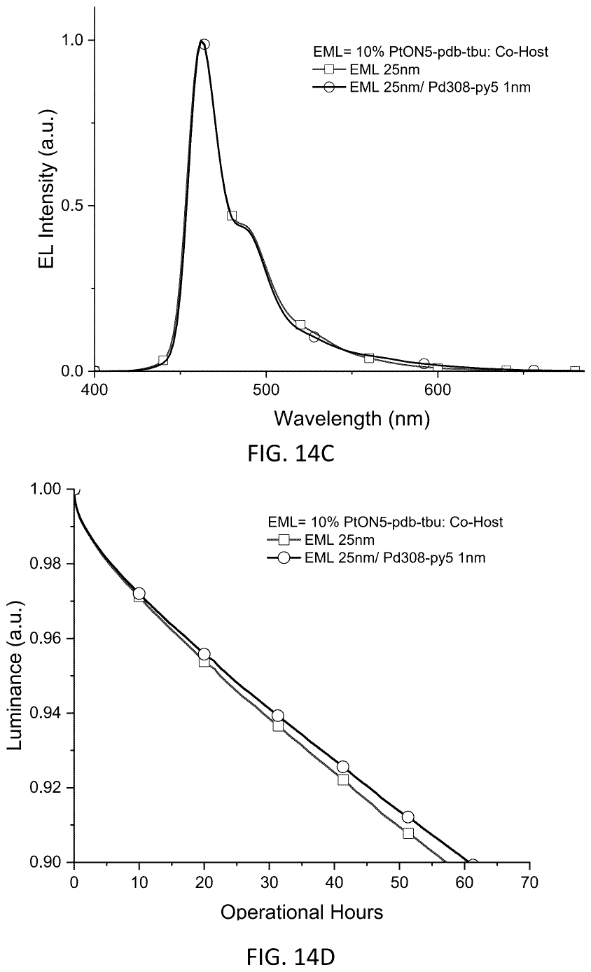

FIG. 14A is a plot of current density-voltage characteristics for devices 1-2 with the structure of:
60 nm ITO/10 nm HATCN/60 nm NPD/5 nm SiBCz/EML/5 nm SiTrzCz2/40 nm 50 wt. % LG201: 50 wt. % Liq/2 nm Liq/100 nm Al
where EML is:
Device 1: 10 wt. % PtON5-pdb-tbu: 60 wt. % SiBCz: 30 wt. % SiTrzCz2 25 nm
Device 2: 10 wt. % PtON5-pdb-tbu: 60 wt. % SiBCz: 30 wt. % SiTrzCz2 25 nm/Pd308-py5 1 nm

FIG. 14B is a plot of EQE versus luminance for devices 1 and 2; FIG. 14C is a plot of EL spectra at current densities of 1 mA cm⁻² of devices 1 and 2; FIG. 14D is a plot of relative luminance versus operational time at a constant current density of 5 mA cm⁻² for devices 1-2.

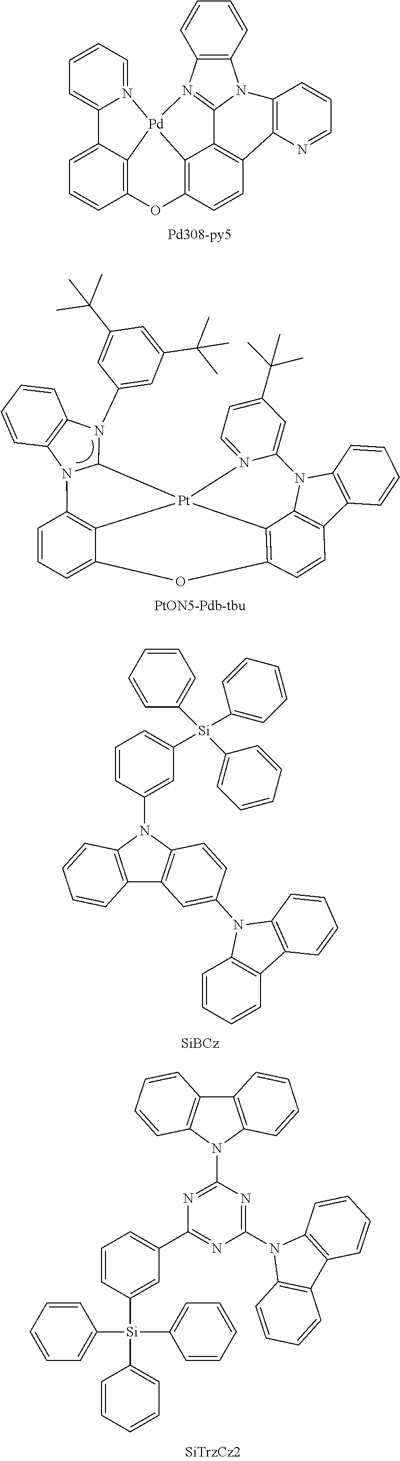

The EQE and device stability are improved with the introduction of a thin Pd308-py5 injection layer. From what is seen in the EL plot, these improvements come with minimal changes in color.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention.

1. An organic light-emitting device, comprising:
a first electrode;
an organic emissive layer disposed over the first electrode;
an electron transport layer disposed directly on the organic emissive layer; and
a second electrode disposed over the electron transport layer;
wherein the electron transport layer has a thickness of less than 10 nm; and
wherein the electron transport layer comprises an aggregate material.

2. The organic light-emitting device of claim 1, wherein the electron transport layer has a thickness of less than 5 nm.

3. (canceled)

4. (canceled)

5. The organic light-emitting device of claim 1, wherein the electron transport layer further comprises a host material.

6. The organic light-emitting device of claim 1, wherein the electron transport layer consists of the aggregate material.

7. The organic light-emitting device of claim 1, wherein the organic light-emitting device emits blue light.

8. The organic light-emitting device of claim 1, wherein the organic light-emitting device emits light of a first wavelength, wherein the first wavelength is between 450 nm and 550 nm.

9. The organic light-emitting device of claim 1, wherein the aggregate material has a first absorption coefficient over a first wavelength, wherein the first absorption coefficient is less than 0.1 cm⁻¹, and wherein the organic light-emitting device emits light of the first wavelength, wherein the first wavelength is from 450-550 nm.

10. The organic light-emitting device of claim 9, wherein the first absorption coefficient is less than 0.01 cm⁻¹.

11. The organic light-emitting device of claim 1, wherein the organic emissive layer has a thickness less than 40 nm.

12. The organic light-emitting device of claim 11, wherein the organic emissive layer has a thickness greater than 15 nm.

13. The organic light-emitting device of claim 1, wherein the aggregate material has a band gap larger than 2.5 eV.

14. The organic light-emitting device of claim 1, wherein the aggregate material comprises a metal complex.

15. The organic light-emitting device of claim 14, wherein the aggregate material comprises a Platinum (Pt) or Palladium (Pd) metal complex.

16. The organic light-emitting device of claim 1, wherein the organic emissive layer comprises a first host material and a second host material;
wherein the first host material is a p-type host; and
wherein the second host material is an n-type host.

17. The organic light-emitting device of claim 1, further comprising an electron blocking layer disposed between the first electrode and the organic emissive layer.

18. The organic light-emitting device of claim 1, wherein the aggregate material is a compound of General Formula I: 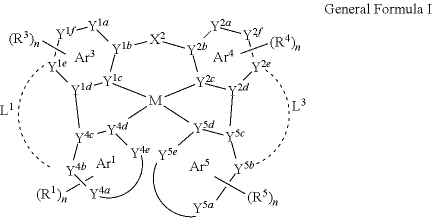
In General Formula I:
M represents Pt(II) or Pd(II);
R¹, R³, R⁴, and R⁵ each independently represents hydrogen, halogen, hydroxyl, nitro, cyanide, thiol, or optionally substituted C₁-C₄ alkyl, alkoxy, amino, or aryl;
each n is independently an integer, valency permitting;
Y^{1a}, Y^{1b}, Y^{1c}, Y^{1d}, Y^{1e}, Y^{1f}, Y^{2a}, Y^{2b}, Y^{2c}, Y^{2d}, Y^{2e}, Y^{2f}, Y^{4a}, Y^{4b}, Y^{4c}, Y^{4d}, Y^{4e}, Y^{5a}, Y^{5b}, Y^{5c}, Y^{5d}, and Y^{5e} each independently represents C, N, Si, O, S;
X² represents NR, PR, CRR′, SiRR′, CRR′, SiRR′, O, S, S═O, O═S═O, Se, Se═O, or O═Se═O, where R and R′ each independently represents hydrogen, halogen, hydroxyl, nitro, cyanide, thiol, or optionally substituted C₁-C₄ alkyl, alkoxy, amino, aryl, or heteroaryl;
each of L¹ and L³ is independently present or absent, and if present, represents a substituted or unsubstituted linking atom or group, where a substituted linking atom is bonded to an alkyl, alkoxy, alkenyl, alkynyl, hydroxy, amine, amide, thiol, aryl, heteroaryl, cycloalkyl, or heterocyclyl moiety;
Ar³ and Ar⁴ each independently represents a 6-membered aryl group; and
Ar¹ and Ar⁵ each independently represents a 5- to 10-membered aryl, heteroaryl, fused aryl, or fused heteroaryl.

19. The organic light-emitting device of claim 1, wherein the aggregate material is represented by General Formula II, General Formula III, General Formula IV, General Formula V, General Formula VI, General Formula VII, General Formula VIII, or General Formula IX: 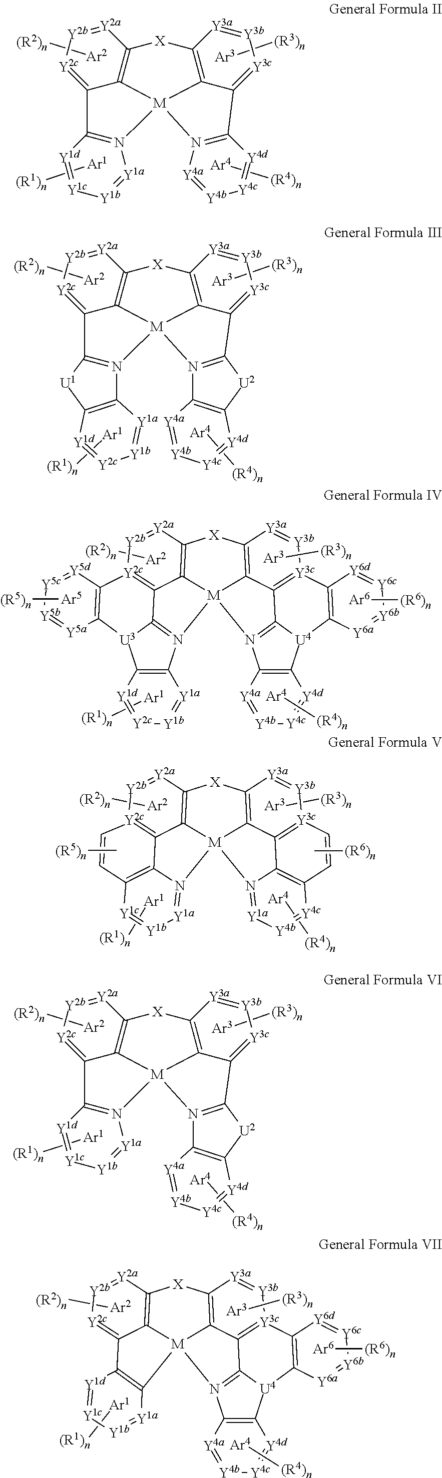 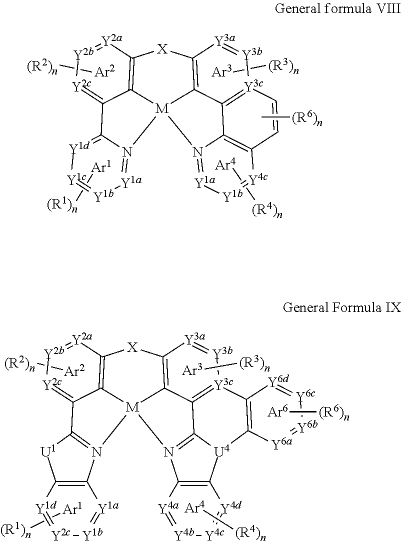
wherein, in General Formulas II-IX:
M represents Pt(II) or Pd(II);
R¹, R², R³, R⁴, R⁵, and R⁶ each independently represents hydrogen, halogen, hydroxyl, nitro, nitrile, thiol, or optionally substituted C₁-C₄ alkyl, alkoxy, amino, or aryl;
each n is independently an integer, valency permitting;
Y^{1a}, Y^{1b}, Y^{1c}, Y^{1d}, Y^{1e}, Y^{1f}, Y^{2a}, Y^{2b}, Y^{2c}, Y^{2d}, Y^{2e}, Y^{2f}, Y^{4a}, Y^{4b}, Y^{4c}, Y^{4d}, Y^{4e}, Y^{5a}, Y^{5b}, Y^{5c}, Y^{5d}, Y^{6a}, Y^{6b}, Y⁶³ and Y^{6d} each independently represents C, N, or Si;
U¹ and U² each independently represents NR, O or S, wherein R represents hydrogen, halogen, hydroxyl, nitro, nitrile, thiol, or optionally substituted C₁-C₄ alkyl, alkoxy, amino, or aryl;
U³ and U⁴ each independently represents N or P; and
X represents O, S, NR, CRR′, SiRR′, PR, BR, S═O, O═S═O, Se, Se═O, or O═Se═O, where R and R′ each independently represents hydrogen, halogen, hydroxyl, nitro, nitrile, thiol, or optionally substituted C₁-C₄ alkyl, alkoxy, amino, aryl, or heteroaryl.

20. The organic light-emitting device of claim 1, wherein the aggregate material has one of the following structures:

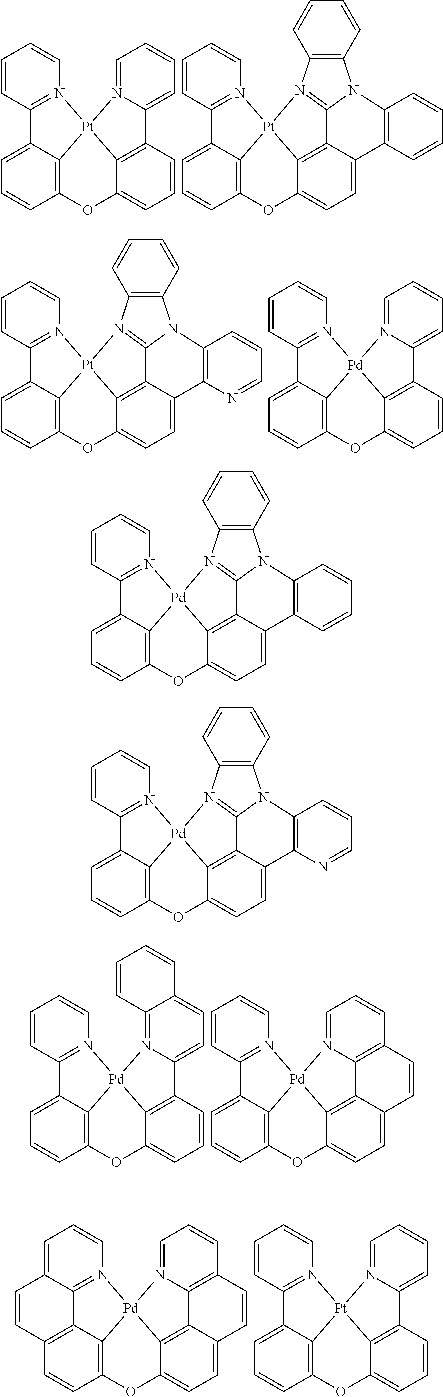

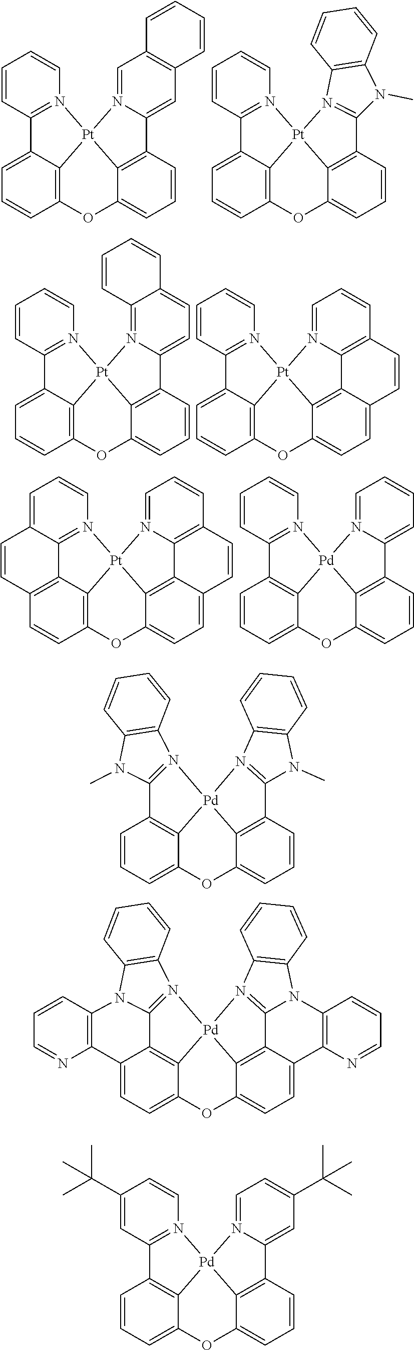

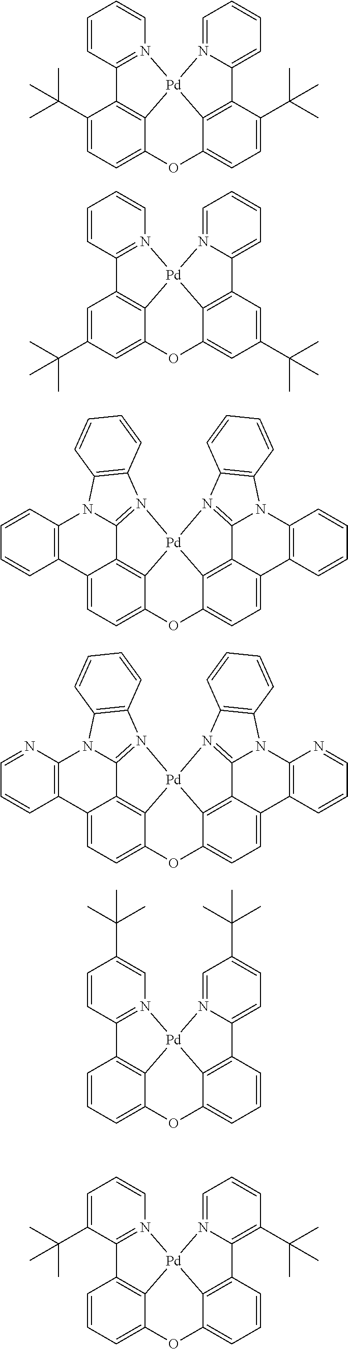

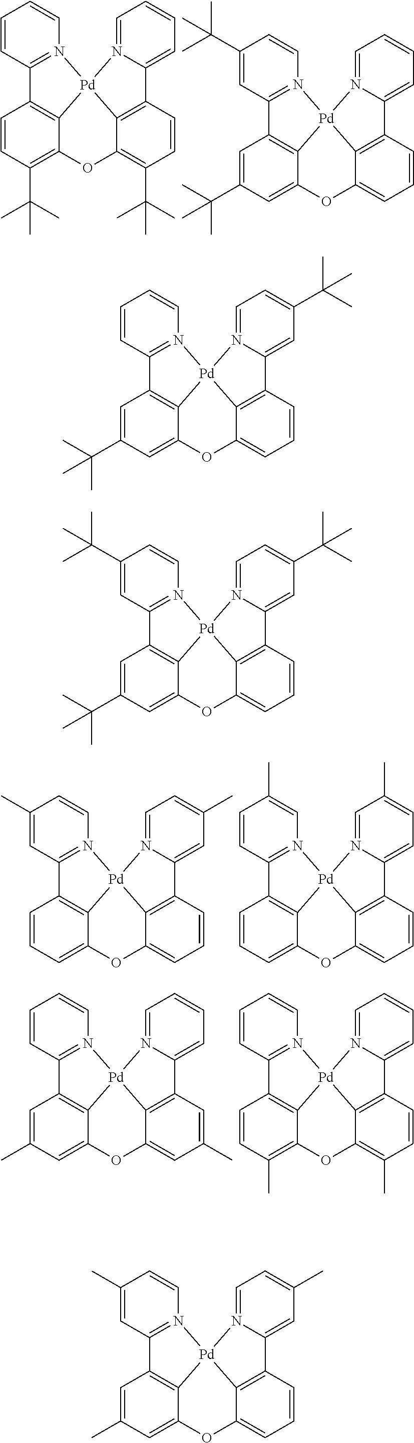

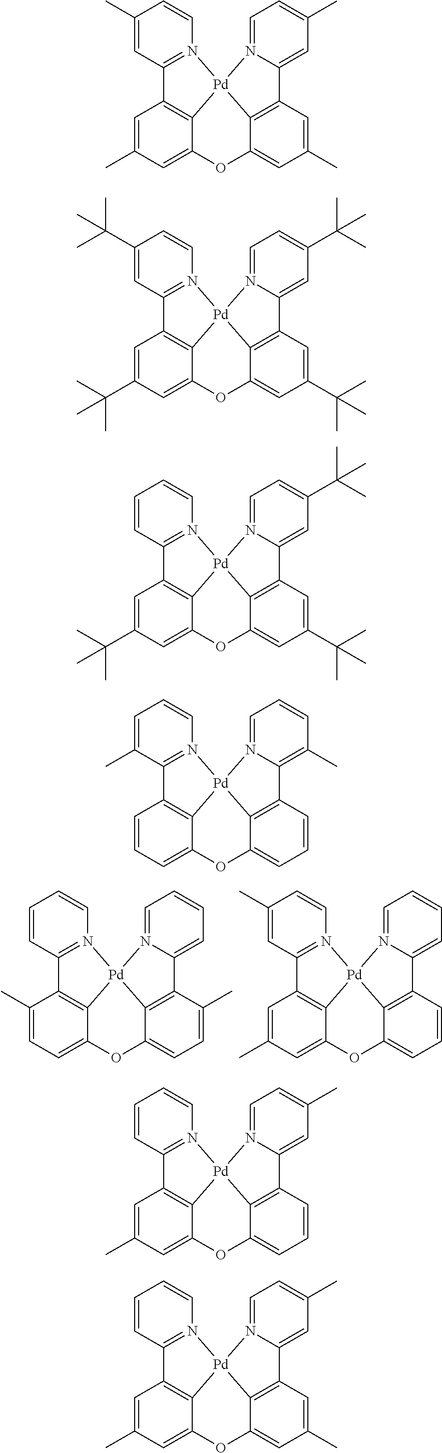

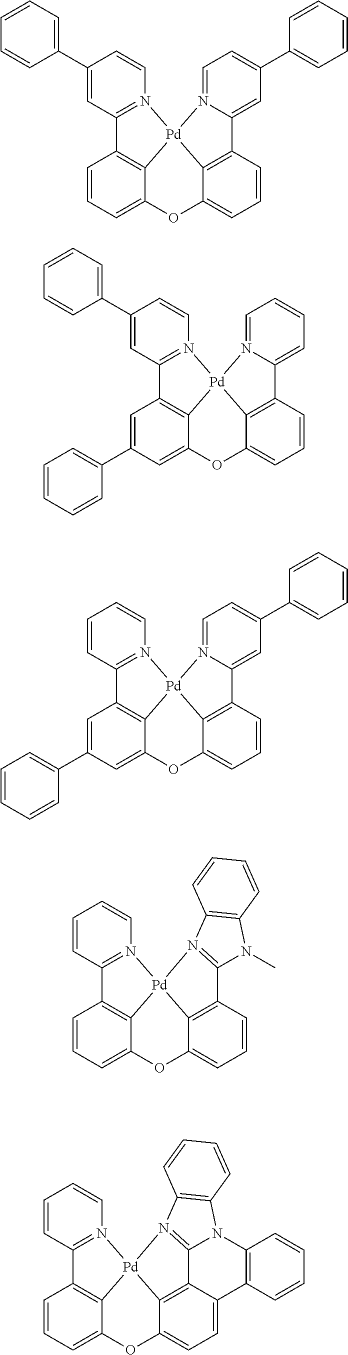

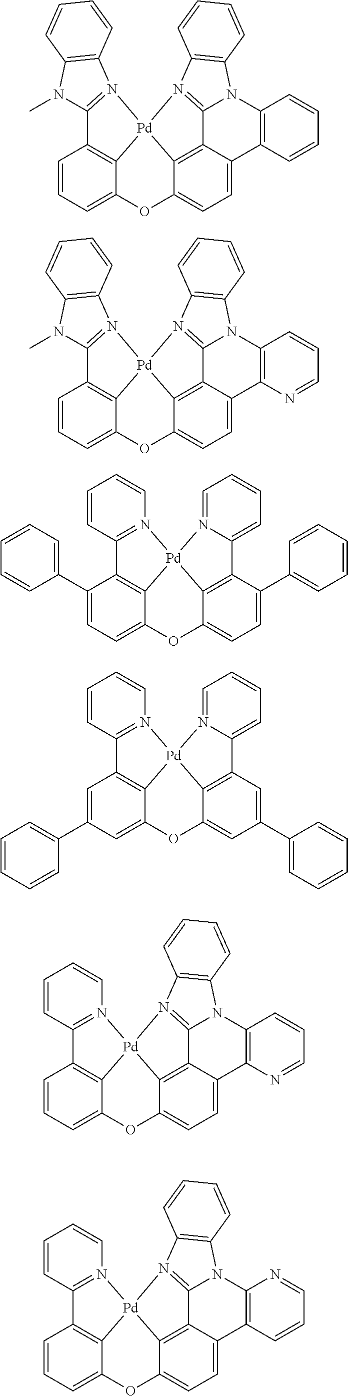

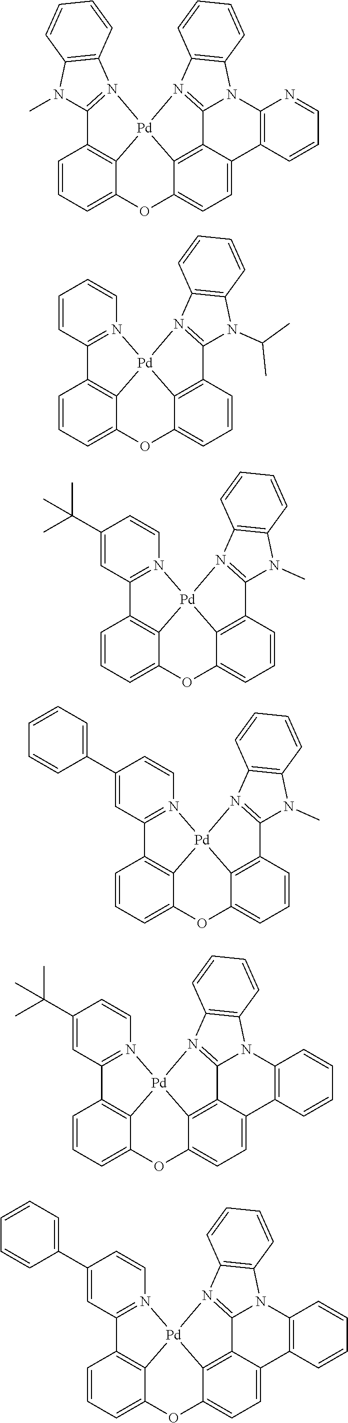

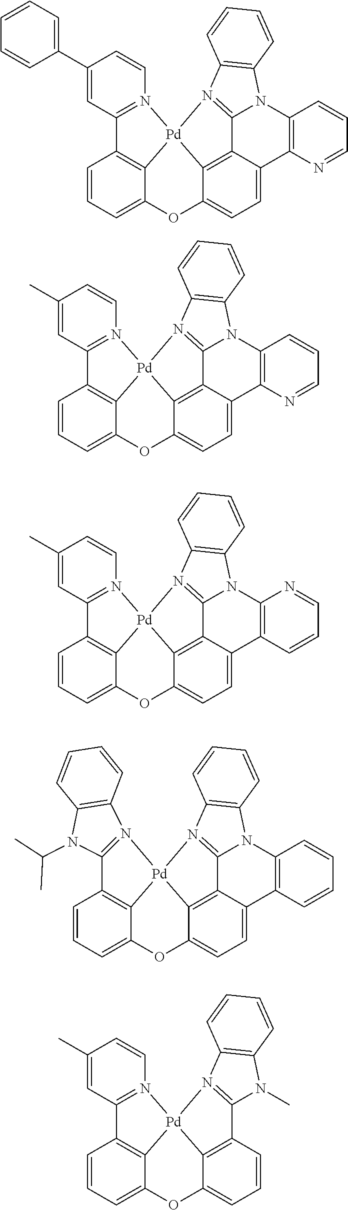

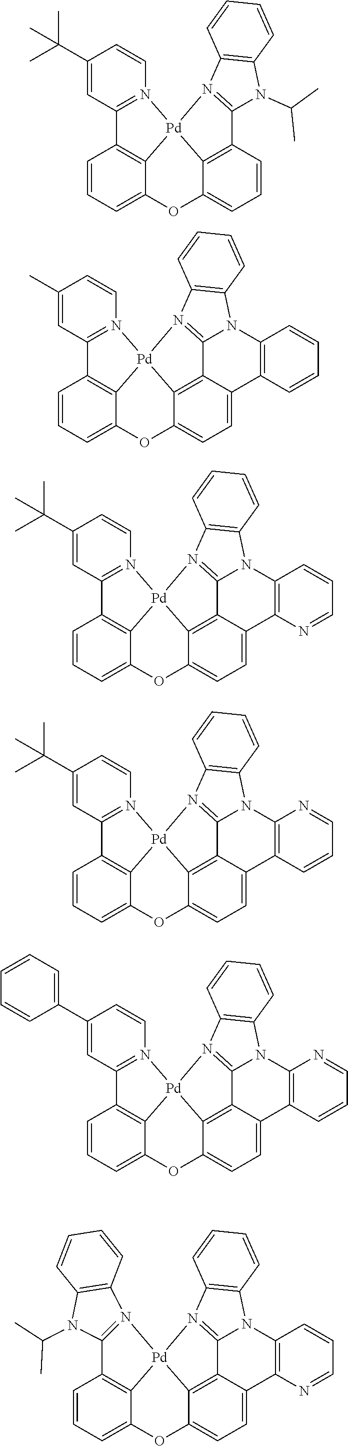

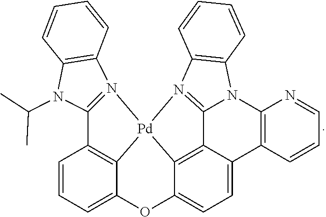

21. The organic light-emitting device of claim 1, wherein the aggregate material is Pd308-py5

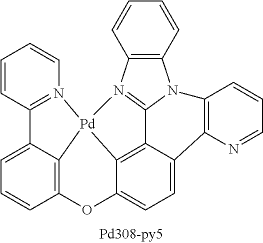

22. A consumer product comprising an organic light-emitting device, wherein the organic light-emitting device comprises:
a first electrode;
an organic emissive layer disposed over the first electrode;
an electron transport layer disposed directly on the organic emissive layer; and
a second electrode disposed over the electron transport layer;
wherein the electron transport layer has a thickness of less than 10 nm; and
wherein the electron transport layer comprises an aggregate material.
